(19) United States
(12) Patent Application Publication
(10) Pub. No.: US 2010/0186804 A1
(43) Pub. Date: Jul. 29, 2010

(54) String Interconnection of Inverted Metamorphic Multijunction Solar Cells on Flexible Perforated Carriers

(75) Inventor: Arthur Cornfeld, Sandia Park, NM (US)

Correspondence Address: EMCORE CORPORATION, 1600 EUBANK BLVD, S.E., ALBUQUERQUE, NM, 87123, US

(73) Assignee: Emcore Solar Power, Inc., Albuquerque, NM (US)

(21) Appl. No.: 12/362,225

(22) Filed: Jan. 29, 2009

(51) Int. Cl. H01L 31/00; H01L 21/02; H01L 31/18

(52) U.S. Cl. 136/255; 438/64; 438/87; 257/E21.002

(57) ABSTRACT

A method of forming a multijunction solar cell string by providing a first multijunction solar cell including a contact pad disposed adjacent the top surface of the multijunction solar cell along a first peripheral edge thereof; providing a second multijunction solar cell disposed adjacent said first multijunction solar cell, having a top surface and a bottom surface, and including a cut-out extending from a second peripheral edge along the top surface of the second solar cell located adjacent the first peripheral edge of said first multijunction solar cell, and extending to a metal contact layer adjacent the bottom surface of said second multijunction solar cell to allow an electrical contact to be made to the metal contact layer; mounting said first and said second multijunction solar cells on a first side of a perforated carrier; attaching a first electrical interconnect to the contact pad of said first multijunction solar cell, the electrical interconnect extending through said perforated carrier; attaching a second electrical interconnect to the metal contact layer of said second multijunction solar cell, the electrical interconnect extending through said perforated carrier; and connecting said first electrical interconnect to said second electrical interconnect.

### REFERENCE TO RELATED APPLICATIONS

This application is related to co-pending U.S. patent application Ser. No. ______ and Ser. No. ______ filed simultaneously herewith.

This application is related to co-pending U.S. patent application Ser. No. 12/337,014 and Ser. No. 12/337,043, filed Dec. 17, 2008.

This application is related to co-pending U.S. patent application Ser. No. 12/271,127 and Ser. No. 12/271,192, filed Nov. 14, 2008.

This application is related to co-pending U.S. patent application Ser. No. 12/267,812, filed Nov. 10, 2008.

This application is related to co-pending U.S. patent application Ser. No. 12/258,190, filed Oct. 24, 2008.

This application is related to co-pending U.S. patent application Ser. No. 12/253,051, filed Oct. 16, 2008.

This application is related to co-pending U.S. patent application Ser. No. 12/190,449, filed Aug. 12, 2008.

This application is related to co-pending U.S. patent application Ser. No. 12/187,477, filed Aug. 7, 2008.

This application is related to co-pending U.S. patent application Ser. No. 12/218,558, and U.S. patent application Ser. No. 12/218,582 filed Jul. 16, 2008.

This application is related to co-pending U.S. patent application Ser. No. 12/123,864, filed May 20, 2008.

This application is related to co-pending U.S. patent application Ser. No. 12/102,550, filed Apr. 14, 2008.

This application is related to co-pending U.S. patent application Ser. No. 12/047,842, and U.S. Ser. No. 12/047,944, filed Mar. 13, 2008.

This application is related to co-pending U.S. patent application Ser. No. 12/023,772, filed Jan. 31, 2008.

This application is related to co-pending U.S. patent application Ser. No. 11/956,069, filed Dec. 13, 2007.

This application is also related to co-pending U.S. patent application Ser. Nos. 11/860,142 and 11/860,183 filed Sep. 24, 2007.

This application is also related to co-pending U.S. patent application Ser. No. 11/836,402, filed Aug. 8, 2007.

This application is also related to co-pending U.S. patent application Ser. No. 11/616,596, filed Dec. 27, 2006.

This application is also related to co-pending U.S. patent application Ser. No. 11/614,332, filed Dec. 21, 2006.

This application is also related to co-pending U.S. patent application Ser. No. 11/445,793, filed Jun. 2, 2006.

This application is also related to co-pending U.S. patent application Ser. No. 11/500,053, filed Aug. 7, 2006.

### GOVERNMENT RIGHTS STATEMENT

This invention was made with government support under Contract No. FA9453-06-C-0345 awarded by the U.S. Air Force. The Government has certain rights in the invention.

### BACKGROUND OF THE INVENTION

1. Field of the Invention

The present invention relates to the field of semiconductor devices, and to fabrication processes and devices such as multijunction solar cells based on III-V semiconductor compounds including a metamorphic layer. Such devices are also known as inverted metamorphic multijunction solar cells.

2. Description of the Related Art

Solar power from photovoltaic cells, also called solar cells, has been predominantly provided by silicon semiconductor technology. In the past several years, however, high-volume manufacturing of III-V compound semiconductor multijunction solar cells for space applications has accelerated the development of such technology not only for use in space but also for terrestrial solar power applications. Compared to silicon, III-V compound semiconductor multijunction devices have greater energy conversion efficiencies and generally more radiation resistance, although they tend to be more complex to manufacture. Typical commercial III-V compound semiconductor multijunction solar cells have energy efficiencies that exceed 27% under one sun, air mass 0 (AM0), illumination, whereas even the most efficient silicon technologies generally reach only about 18% efficiency under comparable conditions. Under high solar concentration (e.g., 500×), commercially available III-V compound semiconductor multijunction solar cells in terrestrial applications (at AM1.5D) have energy efficiencies that exceed 37%. The higher conversion efficiency of III-V compound semiconductor solar cells compared to silicon solar cells is in part based on the ability to achieve spectral splitting of the incident radiation through the use of a plurality of photovoltaic regions with different band gap energies, and accumulating the current from each of the regions.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as payloads become more sophisticated, the power-to-weight ratio of a solar cell becomes increasingly more important, and there is increasing interest in lighter weight, “thin film” type solar cells having both high efficiency and low mass.

Typical III-V compound semiconductor solar cells are fabricated on a semiconductor wafer in vertical, multijunction structures. The individual solar cells or wafers are then disposed in horizontal arrays, with the individual solar cells connected together in an electrical series circuit. The shape and structure of an array, as well as the number of cells it contains, are determined in part by the desired output voltage and current.

Inverted metamorphic solar cell structures based on III-V compound semiconductor layers, such as described in M. W. Wanlass et al., Lattice Mismatched Approaches for High Performance, III-V Photovoltaic Energy Converters (Conference Proceedings of the 31^{st} IEEE Photovoltaic Specialists Conference, Jan. 3-7, 2005, IEEE Press, 2005), present an important conceptual starting point for the development of future commercial high efficiency solar cells. However, the materials and structures for a number of different layers of the cell proposed and described in such reference present a number of practical difficulties, particularly relating to the most appropriate choice of materials and fabrication steps.

### SUMMARY OF THE INVENTION

Briefly, and in general terms, the present invention provides a method of forming a multijunction solar cell string comprising: providing a first multijunction solar cell including a contact pad disposed adjacent the top surface of the multijunction solar cell along a first peripheral edge thereof; providing a second multijunction solar cell disposed adjacent said first multijunction solar cell, having a top surface and a bottom surface, and including a cut-out extending from a second peripheral edge along the top surface of the second solar cell located adjacent the first peripheral edge of said first multijunction solar cell, and extending to a metal contact layer adjacent the bottom surface of said second multijunction solar cell to allow an electrical contact to be made to the metal contact layer; mounting said first and said second multijunction solar cells on a first side of a perforated carrier; attaching a first electrical interconnect to the contact pad of said first multijunction solar cell, a portion of the electrical interconnect extending through said perforated carrier; attaching a second electrical interconnect to the metal contact layer of said second multijunction solar cell, a portion of the electrical interconnect extending through said perforated carrier; mounting a cover glass over each of said first and said second multijunction solar cells; and connecting said first electrical interconnect to said second electrical interconnect.

In another aspect the present invention provides a string of multijunction solar cells including first and second solar cells each with at least an upper and a lower subcell, including at least one metal contact pad to the upper subcell disposed along a first peripheral edge of said solar cells; a metal contact layer adjacent to the lower subcell for making an electrical contact thereto; a cut-out extending from a second peripheral edge along the top surface of the solar cell to the metal contact layer to allow an electrical contact to be made to the lower subcell from the top surface of the solar cell; comprising a perforated carrier on which the solar cells are mounted; a first electrical interconnect extending from the metal contract pad of the first solar cell through the perforated carrier; and a second electrical interconnect extending from the metal contact layer of the adjacent second solar cell and electrically connected to the first electrical interconnect, thereby electrically connecting the first and second solar cells.

In another aspect the present invention provides a solar cell having at least an upper and a lower subcell, including at least one metal contact pad to the upper subcell disposed along a first peripheral edge of said solar cell; a metal contact layer adjacent to the lower subcell for making an electrical contact thereto; a cut-out extending from a second peripheral edge along the top surface of the solar cell to the metal contact layer to allow an electrical contact to be made to the lower subcell from the top surface of the solar cell; comprising a perforated carrier having a top side on which the solar cells are mounted; a first electrical interconnect extending from the metal contact pad of the first solar cell through the perforated carrier; and a bypass diode mounted on the underside of the perforated carrier and having a first terminal connected the first electrical interconnect and a second terminal connected the second electrical interconnect thereby electrically connecting with reverse polarity in parallel the solar cell and the bypass diode.

In another aspect the present invention provides a string of multijunction solar cells including first and second solar cells, each solar cell having at least an upper and a lower subcell, including at least one metal contact pad to the upper subcell disposed along a first peripheral edge of said solar cell; a metal contact layer adjacent to the lower subcell for making an electrical contact thereto; and a cut-out extending from a second peripheral edge along the top surface of the solar cell to the metal contact layer to allow an electrical contact to be made to the lower subcell from the top surface of the solar cell; comprising a perforated carrier having a top side on which the solar cells are mounted; a first electrical interconnect extending from the metal contract pad of the first solar cell through the perforated carrier; and a plurality of bypass diodes mounted on the underside of the perforated carrier, each bypass diode disposed opposite a respective solar cell and having a first terminal (e.g., p+) connected the first electrical interconnect (n+) of the respective solar cell, and a second terminal (n+) connected the second electrical interconnect (p+) the respective solar cell, thereby electrically connecting in parallel each of the solar cells with a respective bypass diode.

Some implementations of the present invention may incorporate or implement fewer of the aspects and features noted in the foregoing summaries.

Additional aspects, advantages, and novel features of the present invention will become apparent to those skilled in the art from this disclosure, including the following detailed description as well as by practice of the invention. While the invention is described below with reference to preferred embodiments, it should be understood that the invention is not limited thereto. Those of ordinary skill in the art having access to the teachings herein will recognize additional applications, modifications and embodiments in other fields, which are within the scope of the invention as disclosed and claimed herein and with respect to which the invention could be of utility.

### BRIEF DESCRIPTION OF THE DRAWINGS

The invention will be better and more fully appreciated by reference to the following detailed description when considered in conjunction with the accompanying drawings, wherein:

FIG. 1 is a graph representing the bandgap of certain binary materials and their lattice constants;

FIG. 2 is a cross-sectional view of the solar cell of the invention after the deposition of semiconductor layers on the growth substrate;

FIG. 3 is a cross-sectional view of the solar cell of FIG. 2 after the next process step;

FIG. 4 is a cross-sectional view of the solar cell of FIG. 3 after the next process step;

FIG. 5A is a cross-sectional view of the solar cell of FIG. 4 after the next process step in which a surrogate substrate is attached;

FIG. 5B is a cross-sectional view of the solar cell of FIG. 5A after the next process step in which the original substrate is removed;

FIG. 5C is another cross-sectional view of the solar cell of FIG. 5B with the surrogate substrate on the bottom of the Figure;

FIG. 6 is a simplified cross-sectional view of the solar cell of FIG. 5C after the next process step;

FIG. 7 is a cross-sectional view of the solar cell of FIG. 6 after the next process step;

FIG. 8 is a cross-sectional view of the solar cell of FIG. 7 after the next process step;

FIG. 9 is a cross-sectional view of the solar cell of FIG. 8 after the next process step;

FIG. 10A is a top plan view of a wafer in which four solar cells are fabricated;

FIG. 10B is a bottom plan view of the wafer of FIG. 10A;

FIG. 10C is a top plan view of a wafer in which two solar cells are fabricated;

FIG. 11 is a cross-sectional view of the solar cell of FIG. 9 after the next process step;

FIG. 12A is a cross-sectional view of the solar cell of FIG. 11 after the next process step;

FIG. 12B is a cross-sectional view of the solar cell of FIG. 12A after the next process step;

FIG. 13A is a top plan view of the wafer of FIG. 10A depicting the surface view of the trench etched around the cell, after the process step depicted in FIG. 12B;

FIG. 13B is a top plan view of the wafer of FIG. 10C depicting the surface view of the trench etched around the cell, after the process step depicted in FIG. 12B;

FIG. 14A is a cross-sectional view of the solar cell of FIG. 12B after the next process step in a first embodiment of the present invention;

FIG. 14B is a cross-sectional view of the solar cell of FIG. 12B after the next process step in a second embodiment of the present invention;

FIG. 14C is a cross-sectional view of the solar cell of FIG. 12B after the next process step in a third embodiment of the present invention;

FIG. 14D is a cross-sectional view of the solar cell of FIG. 14A after the next process step of removal of the surrogate substrate;

FIG. 14E is a cross-sectional view of the solar cell of FIG. 14A after the next process step of removal of the surrogate substrate;

FIG. 14F is a cross-sectional view of the solar cell of FIG. 14A after the next process step of removal of the surrogate substrate;

FIG. 15A is a top plan view of mounting a row of solar cells on the flexible perforated carrier;

FIG. 15B is a top plan view of mounting a second row of solar cells on the flexible perforated carrier;

FIG. 15C is a top plan view of the solar cells in the first row of solar cells being electrically interconnected with the solar cells in the second row of solar cells mounted on the flexible perforated carrier;

FIG. 16A is a cross-sectional view of the solar cell of FIG. 14B after the next process step in a third embodiment of the present invention;

FIG. 16A is a cross-sectional view of two of the solar cells depicted in FIG. 15A as seen from the A-A plane indicated in FIG. 15A;

FIG. 16B is a cross-sectional view of the solar cells depicted in FIG. 16A after the next process step;

FIG. 16C is a cross-sectional view of the solar cells depicted in FIG. 16B after the next process step;

FIG. 16D is a cross-sectional view of the solar cells depicted in FIG. 16C after the next process step in some embodiments;

FIG. 16E is a cross-sectional view of the solar cells depicted in FIG. 16D after the next process step in some embodiments;

FIG. 17A is a cross-sectional view of one of the solar cells depicted in FIG. 15A as seen from the D-D plane indicated in FIG. 15A in another embodiment of the present invention;

FIG. 17B is a cross-sectional view of two of the solar cells depicted in FIG. 15B as seen from the E-E plane indicated in FIG. 15B in a second embodiment of the present invention;

FIG. 17C is a cross-sectional view the solar cells depicted in FIG. 17B, in some embodiments;

FIG. 17D is a cross-sectional view of the solar cells depicted in FIG. 17C, after the next process step in some embodiments;

FIG. 18 is a graph that depicts the current and voltage characteristics of an inverted metamorphic multijunction solar cell according to the present invention; and

FIG. 19 is a graph of the doping profile in the base and emitter layers of a subcell in the metamorphic solar cell according to the present invention.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

The basic concept of fabricating an inverted metamorphic multijunction (IMM) solar cell is to grow the subcells of the solar cell on a substrate in a “reverse” sequence. That is, the high band gap subcells (i.e. subcells with band gaps in the range of 1.8 to 2.1 eV), which would normally be the “top” subcells facing the solar radiation, are initially grown epitaxially directly on a semiconductor growth substrate, such as for example GaAs or Ge, and such subcells are consequently lattice-matched to such substrate. One or more lower band gap middle subcells (i.e. with band gaps in the range of 1.2 to 1.8 eV) can then be grown on the high band gap subcells.

At least one lower subcell is formed over the middle subcell such that the at least one lower subcell is substantially lattice-mismatched with respect to the growth substrate and such that at least one lower subcell has a third lower band gap (i.e., a band gap in the range of 0.7 to 1.2 eV). A surrogate substrate or support structure is then attached or provided over the “bottom” or substantially lattice-mismatched lower subcell, and the growth semiconductor substrate is subsequently removed. (The growth substrate may then subsequently be re-used for the growth of a second and subsequent solar cells).

A variety of different features and aspects of inverted metamorphic multijunction solar cells are disclosed in the related applications noted above. Some or all of such features may be included in the structures and processes associated with the solar cells of the present invention. More particularly, one aspect of an embodiment of the present application is directed to the feature of providing a metal contact layer adjacent to the lower solar subcell for making an electrical contact thereto; attaching an interconnect to the electrical contact; and mounting the solar cell on a flexible perforated carrier. In some embodiments, at least a portion of the interconnect extends through the perforated carrier. In other embodiments, the interconnect provides an electrical interconnection to an adjacently mounted solar cell on the carrier, either directly, or by electrical connection to another interconnect mounted on the adjacent solar cell. Such aspect may or may not be included in the structures and processes associated with other embodiments of solar cells of the present invention.

Another aspect of an embodiment of the present application is directed to the feature of mounting the solar cell on the top side of a flexible perforated carrier; mounting a bypass diode on the underside of the flexible perforated carrier; and attaching an electrical interconnect from the solar cell to the bypass diode wherein at least a portion of the interconnect extends through the perforated carrier. Such aspect may or may not be included in the structures and processes associated with other embodiments of solar cells of the present invention.

It should be apparent to one skilled in the art that the inclusion of additional metal contact pads or cut-outs, or semiconductor layers within the cell with similar or additional functions and properties, is also within the scope of the present invention.

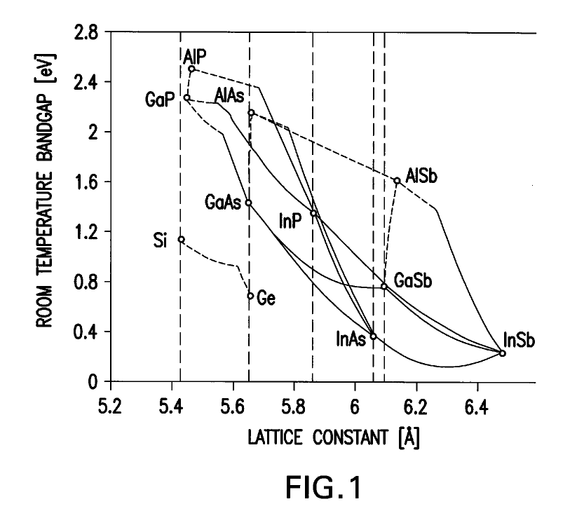

FIG. 1 is a graph representing the band gap of certain binary materials and their lattice constants. The band gap and lattice constants of ternary materials are located on the lines drawn between typical associated binary materials (such as the ternary material GaAlAs being located between the GaAs and AlAs points on the graph, with the band gap of the ternary material lying between 1.42 eV for GaAs and 2.16 eV for AlAs depending upon the relative amount of the individual constituents). Thus, depending upon the desired band gap, the material constituents of ternary materials can be appropriately selected for growth.

The lattice constants and electrical properties of the layers in the semiconductor structure are preferably controlled by specification of appropriate reactor growth temperatures and times, and by use of appropriate chemical composition and dopants. The use of a vapor deposition method, such as Organo Metallic Vapor Phase Epitaxy (OMVPE), Metal Organic Chemical Vapor Deposition (MOCVD), Molecular Beam Epitaxy (MBE), or other vapor deposition methods for the reverse growth may enable the layers in the monolithic semiconductor structure forming the cell to be grown with the required thickness, elemental composition, dopant concentration and grading and conductivity type.

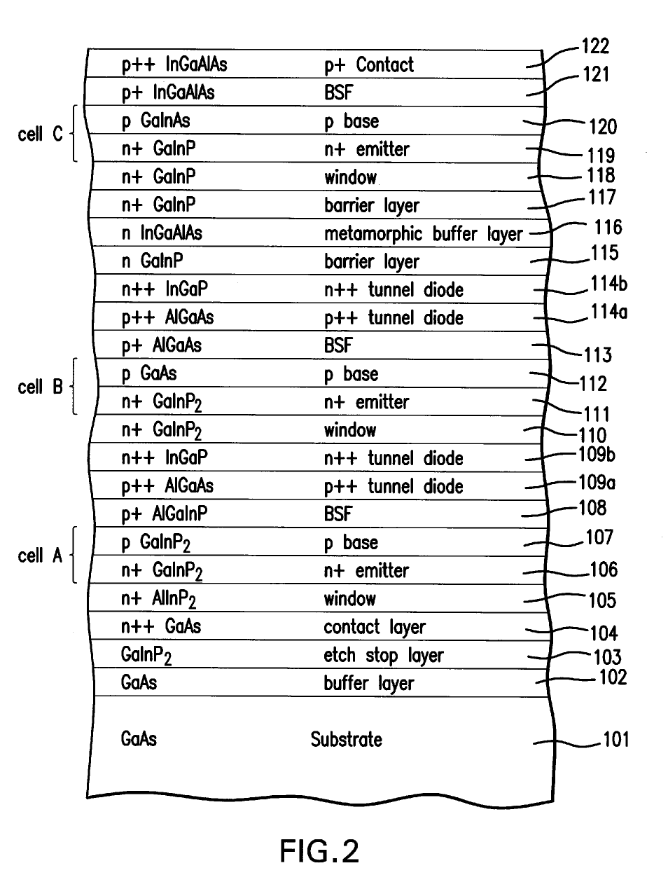

FIG. 2 depicts the multijunction solar cell according to the present invention after the sequential formation of the three subcells A, B and C on a GaAs growth substrate. More particularly, there is shown a substrate 101, which is preferably gallium arsenide (GaAs), but may also be germanium (Ge) or other suitable material. For GaAs, the substrate is preferably a 15° off-cut substrate, that is to say, its surface is orientated 15° off the (100) plane towards the (111) A plane, as more fully described in U.S. patent application Ser. No. 12/047,944, filed Mar. 13, 2008. Other alternative growth substrates, such as described in U.S. patent application Ser. No. 12/337,014, filed Dec. 17, 2008, maybe used as well.

In the case of a Ge substrate, a nucleation layer (not shown) is deposited directly on the substrate 101. On the substrate, or over the nucleation layer (in the case of a Ge substrate), a buffer layer 102 and an etch stop layer 103 are further deposited. In the case of GaAs substrate, the buffer layer 102 is preferably GaAs. In the case of Ge substrate, the buffer layer 102 is preferably InGaAs. A contact layer 104 of GaAs is then deposited on layer 103, and a window layer 105 of AlInP is deposited on the contact layer. The subcell A, consisting of an n+ emitter layer 106 and a p-type base layer 107, is then epitaxially deposited on the window layer 105. The subcell A is generally latticed matched to the growth substrate 101.

It should be noted that the multijunction solar cell structure could be formed by any suitable combination of group III to V elements listed in the periodic table subject to lattice constant and bandgap requirements, wherein the group III includes boron (B), aluminum (Al), gallium (Ga), indium (In), and thallium (T). The group IV includes carbon (C), silicon (Si), germanium (Ge), and tin (Sn). The group V includes nitrogen (N), phosphorus (P), arsenic (As), antimony (Sb), and bismuth (Bi).

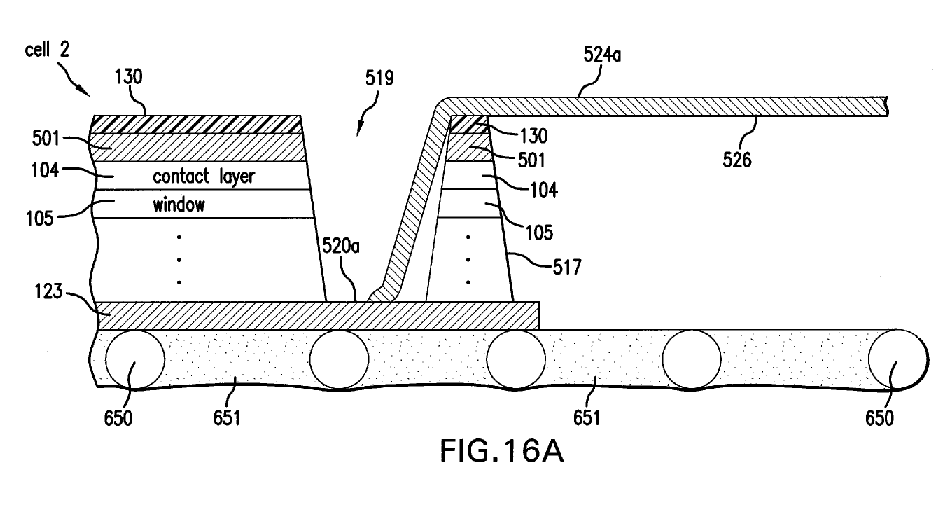

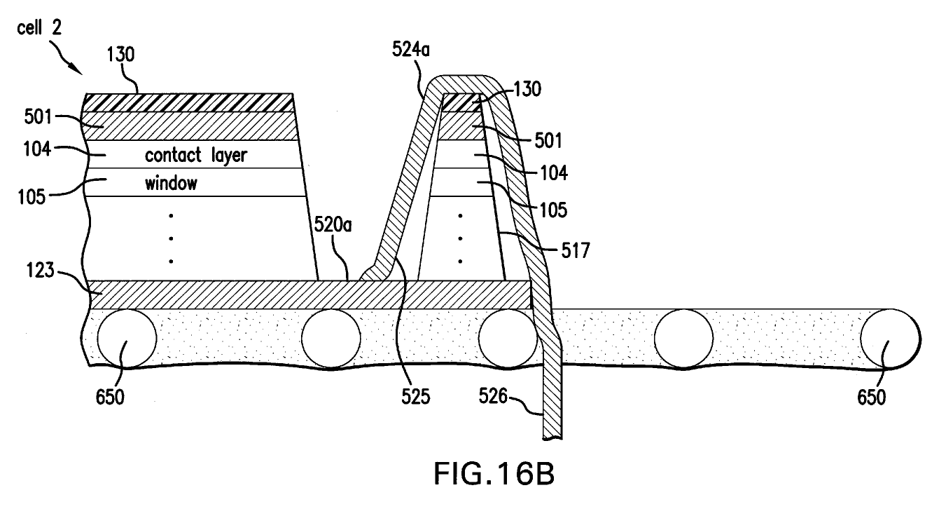

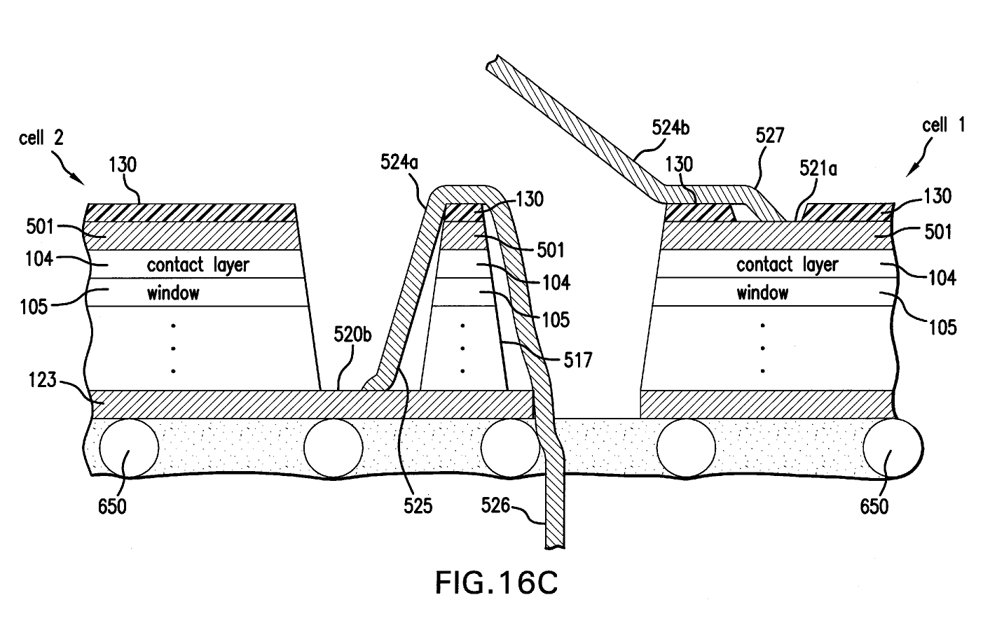

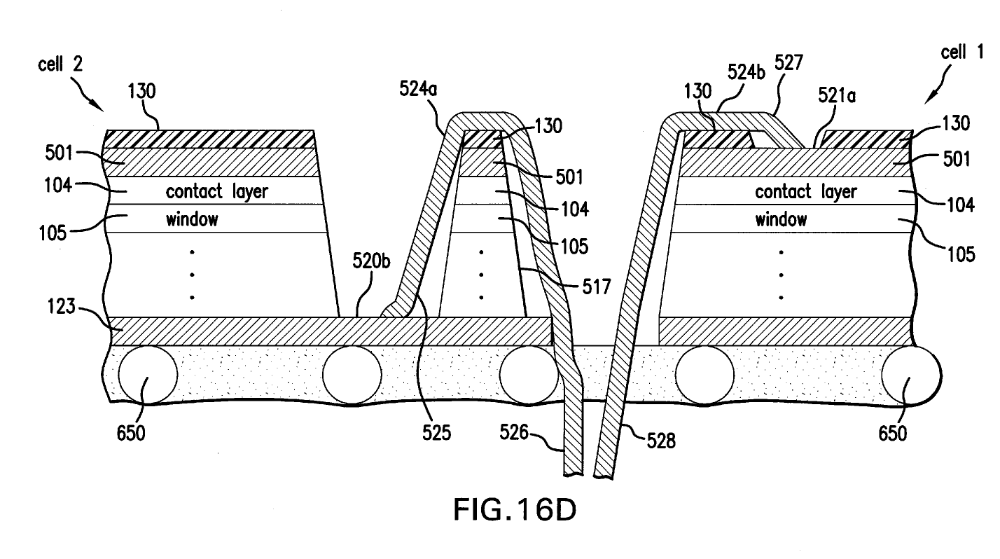

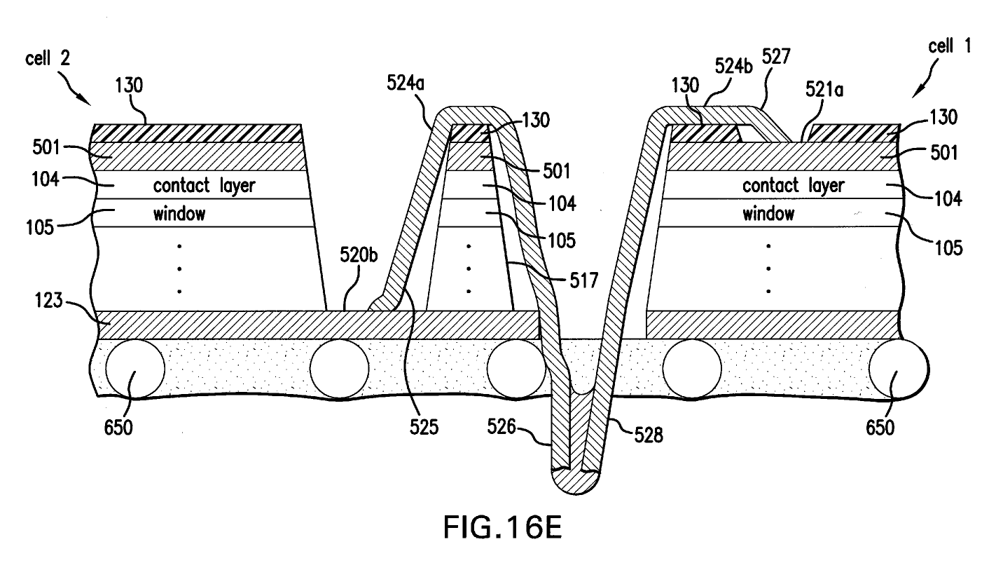

In the preferred embodiment, the emitter layer 106 is composed of InGa(Al)P and the base layer 107 is composed of InGa(Al)P. The aluminum or Al term in parenthesis in the preceding formula means that Al is an optional constituent, and in this instance may be used in an amount ranging from 0% to 30%. The doping profile of the emitter and base layers 106 and 107 according to the present invention will be discussed in conjunction with FIG. 16.

Subcell A will ultimately become the “top” subcell of the inverted metamorphic structure after completion of the process steps according to the present invention to be described hereinafter.

On top of the base layer 107 a back surface field (“BSF”) layer 108 preferably p+ AlGaInP is deposited and used to reduce recombination loss.

The BSF layer 108 drives minority carriers from the region near the base/BSF interface surface to minimize the effect of recombination loss. In other words, a BSF layer 18 reduces recombination loss at the backside of the solar subcell A and thereby reduces the recombination in the base.

On top of the BSF layer 108 is deposited a sequence of heavily doped p-type and n-type layers 109a and 109b that form a tunnel diode, i.e. an ohmic circuit element that connects subcell A to subcell B. Layer 109a is preferably composed of p++ AlGaAs, and layer 109b is preferably composed of n++ InGaP.

On top of the tunnel diode layers 109 a window layer 110 is deposited, preferably n+ InGaP. The advantage of utilizing InGaP as the material constituent of the window layer 110 is that it has an index of refraction that closely matches the adjacent emitter layer 111, as more fully described in U.S. patent application Ser. No. 12/258,190, filed Oct. 24, 2008. More generally, the window layer 110 used in the subcell B operates to reduce the interface recombination loss. It should be apparent to one skilled in the art, that additional layer(s) may be added or deleted in the cell structure without departing from the scope of the present invention.

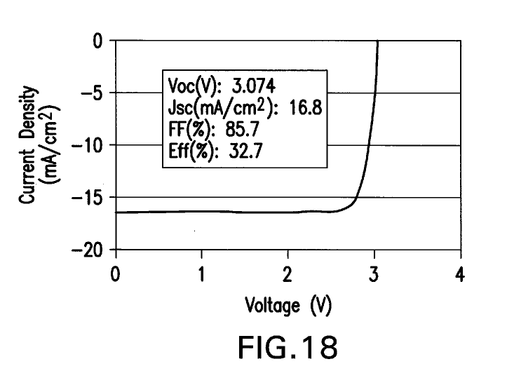

On top of the window layer 110 the layers of subcell B are deposited: the n-type emitter layer 111 and the p-type base layer 112. These layers are preferably composed of InGaP and In_{0.05}GaAs respectively (for a Ge substrate or growth template), or InGaP and GaAs respectively (for a GaAs substrate), although any other suitable materials consistent with lattice constant and bandgap requirements may be used as well. Thus, subcell B may be composed of a GaAs, GaInP, GaInAs, GaAsSb, or GaInAsN emitter region and a GaAs, GaInAs, GaAsSb, or GaInAsN base region. The doping profile of layers 111 and 112 according to the present invention will be discussed in conjunction with FIG. 18.

In previously disclosed implementations of an inverted metamorphic solar cell, the middle cell was a homostructure. In the present invention, similarly to the structure disclosed in U.S. patent application Ser. No. 12/023,772, the middle subcell becomes a heterostructure with an InGaP emitter and its window is converted from InAlP to InGaP. This modification eliminated the refractive index discontinuity at the window/emitter interface of the middle sub-cell. Moreover, the window layer 110 is preferably doped more than that of the emitter 111 to move the Fermi level up closer to the conduction band and therefore create band bending at the window/emitter interface which results in constraining the minority carriers to the emitter layer.

In the preferred embodiment of the present invention, the middle subcell emitter has a band gap equal to the top subcell emitter, and the bottom subcell emitter has a band gap greater than the band gap of the base of the middle subcell. Therefore, after fabrication of the solar cell, and implementation and operation, neither the emitters of middle subcell B nor the bottom subcell C will be exposed to absorbable radiation. Substantially all of the photons representing absorbable radiation will be absorbed in the bases of cells B and C, which have narrower band gaps than the emitters. Therefore, the advantages of using heterojunction subcells are: (i) the short wavelength response for both subcells will improve, and (ii) the bulk of the radiation is more effectively absorbed and collected in the narrower band gap base. The effect will be to increase the short circuit current J_{sc}.

On top of the cell B is deposited a BSF layer 113 which performs the same function as the BSF layer 109. The p++/n++ tunnel diode layers 114a and 114b, respectively, are deposited over the BSF layer 113, similar to the layers 109a and 109b, forming an ohmic circuit element to connect subcell B to subcell C. The layer 114a is preferably composed of p++ AlGaAs, and layer 114b is preferably composed of n++ InGaP.

A barrier layer 115, preferably composed of n-type InGa(Al)P, is deposited over the tunnel diode 114a /114b, to a thickness of about 1.0 micron. Such barrier layer is intended to prevent threading dislocations from propagating, either opposite to the direction of growth into the middle and top subcells B and A, or in the direction of growth into the bottom subcell C, and is more particularly described in copending U.S. patent application Ser. No. 11/860,183, filed Sep. 24, 2007.

A metamorphic layer (or graded interlayer) 116 is deposited over the barrier layer 115 using a surfactant. Layer 116 is preferably a compositionally step-graded series of InGaAlAs layers, preferably with monotonically changing lattice constant, so as to achieve a gradual transition in lattice constant in the semiconductor structure from subcell B to subcell C while minimizing threading dislocations from occurring. The band gap of layer 116 is constant throughout its thickness, preferably approximately equal to 1.5 eV, or otherwise consistent with a value slightly greater than the bandgap of the middle subcell B. The preferred embodiment of the graded interlayer may also be expressed as being composed of (InₓGa₁₋ₓ)_{y} Al_{1-y}As, with x and y selected such that the band gap of the interlayer remains constant at approximately 1.50 eV or other appropriate band gap.

In the surfactant assisted growth of the metamorphic layer 116, a suitable chemical element is introduced into the reactor during the growth of layer 116 to improve the surface characteristics of the layer. In the preferred embodiment, such element may be a dopant or donor atom such as selenium (Se) or tellurium (Te). Small amounts of Se or Te are therefore incorporated in the metamorphic layer 116, and remain in the finished solar cell. Although Se or Te are the preferred n-type dopant atoms, other non-isoelectronic surfactants may be used as well.

Surfactant assisted growth results in a much smoother or planarized surface. Since the surface topography affects the bulk properties of the semiconductor material as it grows and the layer becomes thicker, the use of the surfactants minimizes threading dislocations in the active regions, and therefore improves overall solar cell efficiency.

As an alternative to the use of non-isoelectronic surfactants one may use an isoelectronic surfactant. The term “isoelectronic” refers to surfactants such as antimony (Sb) or bismuth (Bi), since such elements have the same number of valence electrons as the P atom of InGaP, or the As atom in InGaAlAs, in the metamorphic buffer layer. Such Sb or Bi surfactants will not typically be incorporated into the metamorphic layer 116.

In an alternative embodiment where the solar cell has only two subcells, and the “middle” cell B is the uppermost or top subcell in the final solar cell, wherein the “top” subcell B would typically have a bandgap of 1.8 to 1.9 eV, then the band gap of the interlayer would remain constant at 1.9 eV.

In the inverted metamorphic structure described in the Wanlass et al. paper cited above, the metamorphic layer consists of nine compositionally graded InGaP steps, with each step layer having a thickness of 0.25 micron. As a result, each layer of Wanlass et al. has a different bandgap. In the preferred embodiment of the present invention, the layer 116 is composed of a plurality of layers of InGaAlAs, with monotonically changing lattice constant, each layer having the same bandgap, approximately 1.5 eV.

The advantage of utilizing a constant bandgap material such as InGaAlAs is that arsenide-based semiconductor material is much easier to process in standard commercial MOCVD reactors, while the small amount of aluminum assures radiation transparency of the metamorphic layers.

Although the preferred embodiment of the present invention utilizes a plurality of layers of InGaAlAs for the metamorphic layer 116 for reasons of manufacturability and radiation transparency, other embodiments of the present invention may utilize different material systems to achieve a change in lattice constant from subcell B to subcell C. Thus, the system of Wanlass using compositionally graded InGaP is a second embodiment of the present invention. Other embodiments of the present invention may utilize continuously graded, as opposed to step graded, materials. More generally, the graded interlayer may be composed of any of the As, P, N, Sb based III-V compound semiconductors subject to the constraints of having the in-plane lattice parameter greater or equal to that of the second solar cell and less than or equal to that of the third solar cell, and having a bandgap energy greater than that of the second solar cell.

In another embodiment of the present invention, an optional second barrier layer 117 may be deposited over the InGaAlAs metamorphic layer 116. The second barrier layer 117 will typically have a different composition than that of barrier layer 115, and performs essentially the same function of preventing threading dislocations from propagating. In the preferred embodiment, barrier layer 117 is n+ type GaInP.

A window layer 118 preferably composed of n+ type GaInP is then deposited over the barrier layer 117 (or directly over layer 116, in the absence of a second barrier layer). This window layer operates to reduce the recombination loss in subcell “C”. It should be apparent to one skilled in the art that additional layers may be added or deleted in the cell structure without departing from the scope of the present invention.

On top of the window layer 118, the layers of cell C are deposited: the n+ emitter layer 119, and the p-type base layer 120. These layers are preferably composed of n+ type InGaAs and p+ type InGaAs, respectively, or n+ type InGaP and p type InGaAs for a heterojunction subcell, although another suitable materials consistent with lattice constant and bandgap requirements may be used as well. The doping profile of layers 119 and 120 will be discussed in connection with FIG. 18.

A BSF layer 121, preferably composed of InGaAlAs, is then deposited on top of the cell C, the BSF layer performing the same function as the BSF layers 108 and 113.

Finally a high band gap contact layer 122, preferably composed of InGaAlAs, is deposited on the BSF layer 121.

This contact layer added to the bottom (non-illuminated) side of a lower band gap photovoltaic cell, in a single or a multijunction photovoltaic cell, can be formulated to reduce absorption of the light that passes through the cell, so that (1) an ohmic metal contact layer below (non-illuminated side) it will also act as a mirror layer, and (2) the contact layer doesn't have to be selectively etched off, to prevent absorption.

It should be apparent to one skilled in the art that additional layer(s) may be added or deleted in the cell structure without departing from the scope of the present invention.

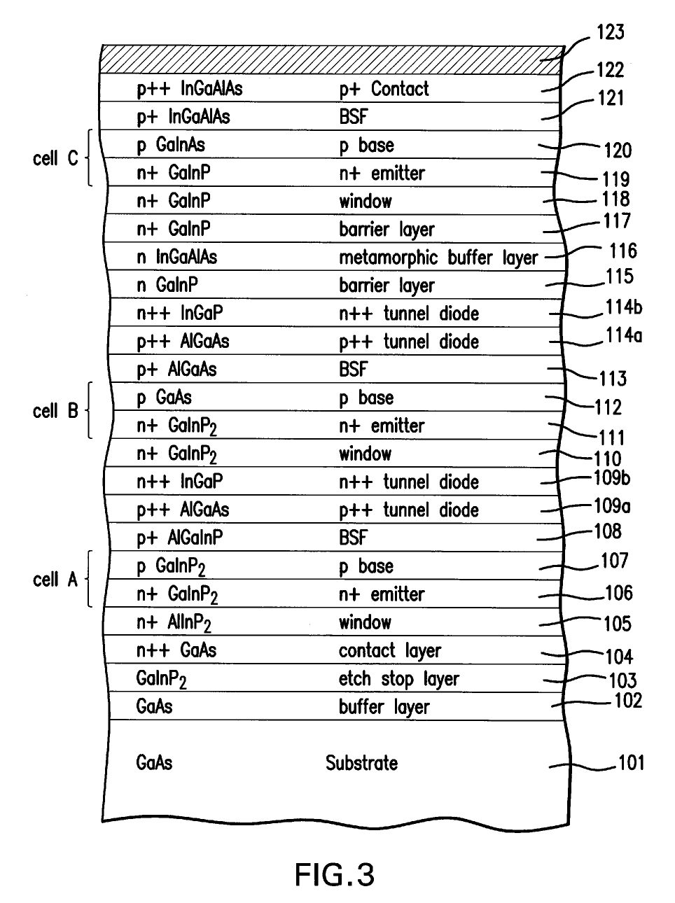

FIG. 3 is a cross-sectional view of the solar cell of FIG. 2 after the next process step in which a metal contact layer 123 is deposited over the p+ semiconductor contact layer 122. The metal is preferably the sequence of metal layers Ti/Au/Ag/Au or Ti/Pd/Ag, although other suitable sequences and materials may be used as well.

Also, the metal contact scheme chosen is one that has a planar interface with the semiconductor, after heat treatment to activate the ohmic contact. This is done so that (i) a dielectric layer separating the metal from the semiconductor doesn't have to be deposited and selectively etched in the metal contact areas; and (ii) the contact layer is specularly reflective over the wavelength range of interest.

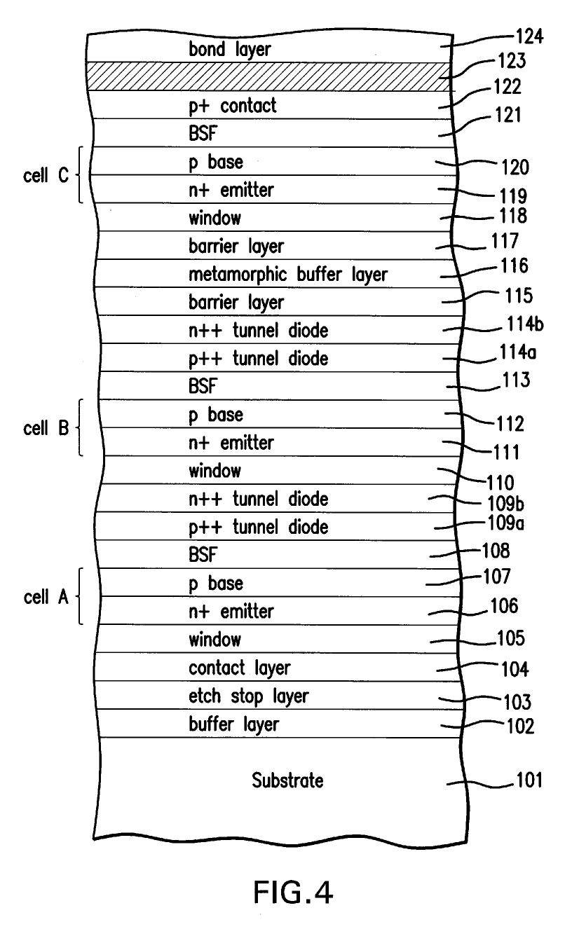

FIG. 4 is a cross-sectional view of the solar cell of FIG. 3 after the next process step in which a bonding layer 124 is deposited over the metal layer 123. In one embodiment of the present invention, the bonding layer is an adhesive, preferably Wafer Bond (manufactured by Brewer Science, Inc. of Rolla, Mo.). In other embodiments of the present invention, a solder or eutectic bonding layer 124, such as described in U.S. patent application Ser. No. 12/271,127 filed Nov. 14, 2008, or a bonding layer 124 such as described in U.S. patent application Ser. No. 12/265,113, filed Nov. 5, 2008, may be used, where the surrogate substrate remains a permanent supporting component of the finished solar cell.

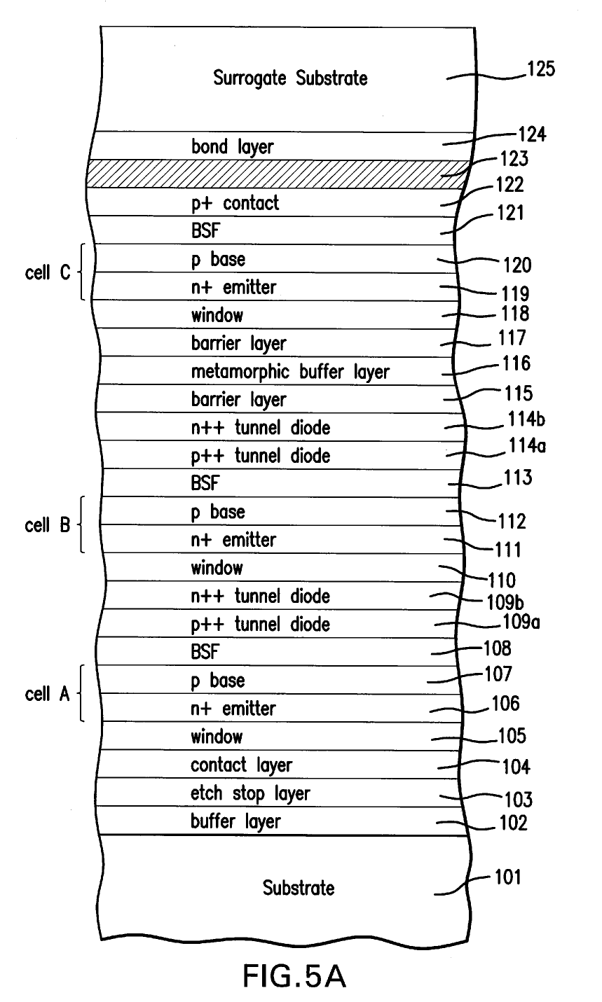

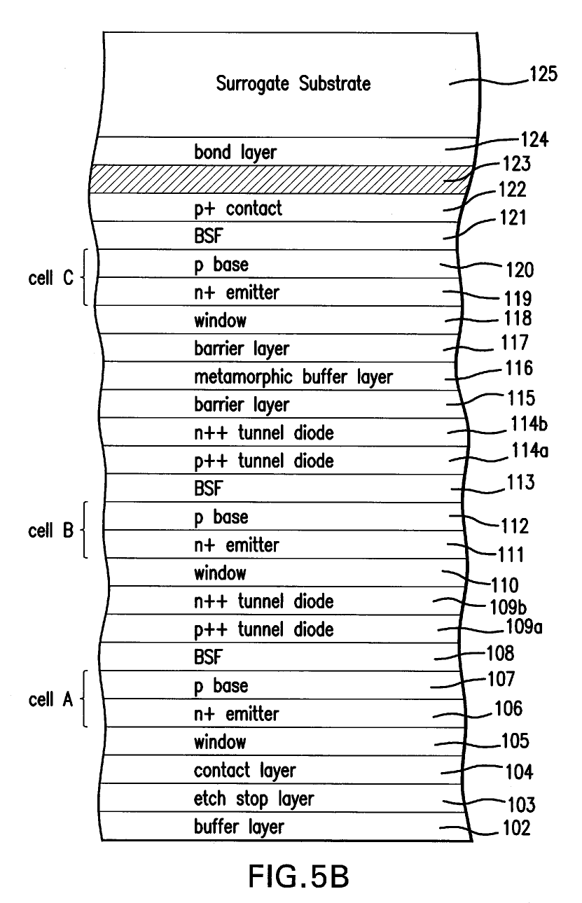

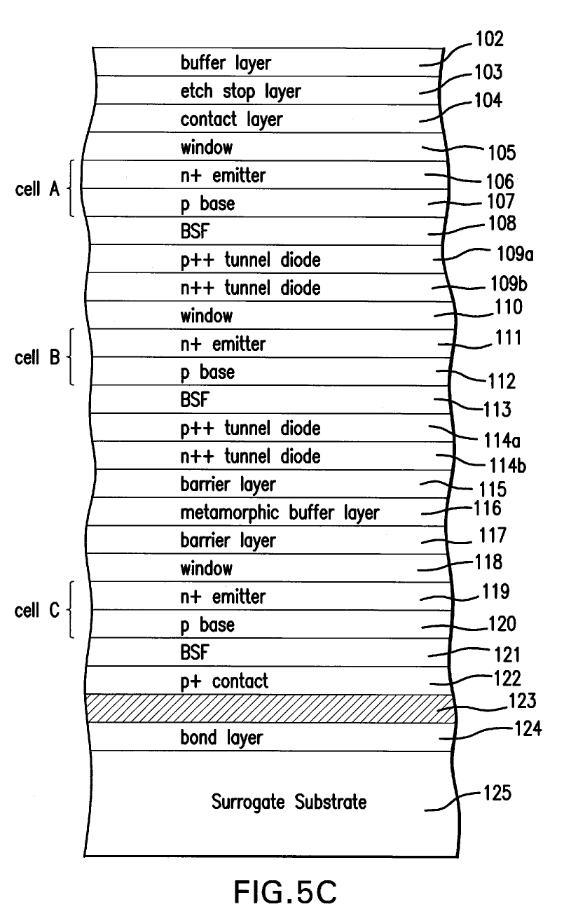

FIG. 5A is a cross-sectional view of the solar cell of FIG. 4 after the next process step in which a surrogate substrate 125, preferably sapphire, is attached. Alternatively, the surrogate substrate may be GaAs, Ge or Si, or other suitable material. The surrogate substrate is about 40 mils in thickness, and in the case of embodiments in which the surrogate substrate is to be removed, it is perforated with holes about 1 mm in diameter, spaced 4 mm apart, to aid in subsequent removal of the adhesive and the substrate.

FIG. 5B is a cross-sectional view of the solar cell of FIG. 5A after the next process step in which the original substrate is removed by a sequence of lapping, grinding and/or etching steps in which the substrate 101, and the buffer layer 102 are removed. The choice of a particular etchant is growth substrate dependent.

FIG. 5C is a cross-sectional view of the solar cell of FIG. 5B with the orientation with the surrogate substrate 125 being at the bottom of the Figure. Subsequent Figures in this application will assume such orientation.

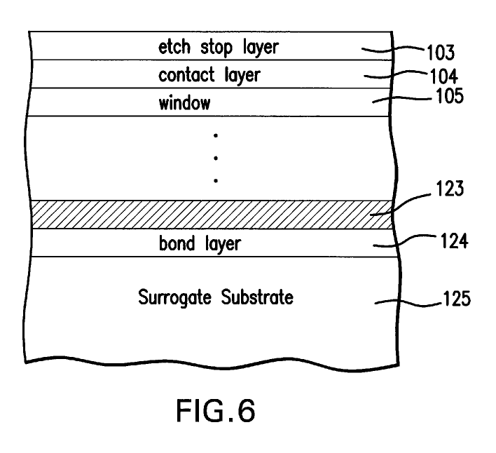

FIG. 6 is a simplified cross-sectional view of the solar cell of FIG. 5B depicting just a few of the top layers and lower layers over the surrogate substrate 125.

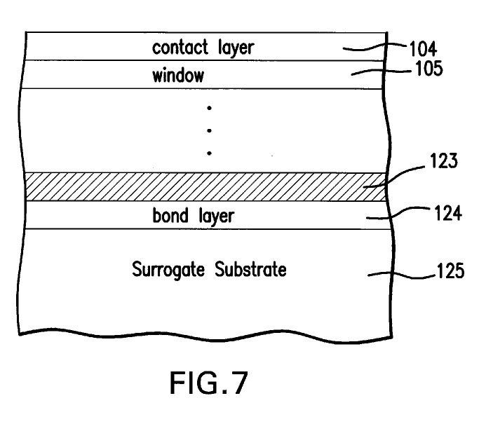

FIG. 7 is a cross-sectional view of the solar cell of FIG. 6 after the next process step in which the etch stop layer 103 is removed by a HCl/H₂O solution.

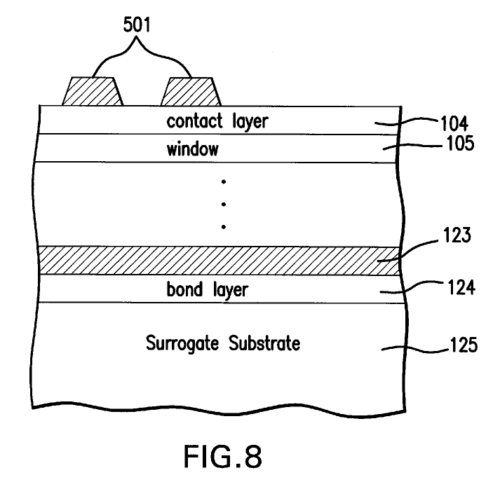

FIG. 8 is a cross-sectional view of the solar cell of FIG. 7 after the next sequence of process steps in which a photoresist mask (not shown) is placed over the contact layer 104 to form the grid lines 501. As will be described in greater detail below, the grid lines 501 are deposited via evaporation and lithographically patterned and deposited over the contact layer 104. The mask is subsequently lifted off to form the finished metal grid lines 501 as depicted in the Figures.

As more fully described in U.S. patent application Ser. No. 12/218,582 filed Jul. 18, 2008, hereby incorporated by reference, the grid lines 501 are preferably composed of the sequence of layers Pd/Ge/Ti/Pd/Au, although other suitable sequences and materials may be used as well.

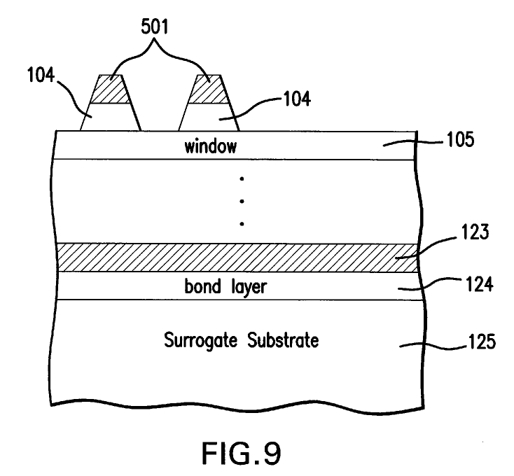

FIG. 9 is a cross-sectional view of the solar cell of FIG. 8 after the next process step in which the grid lines are used as a mask to etch down the surface to the window layer 105 using a citric acid/peroxide etching mixture.

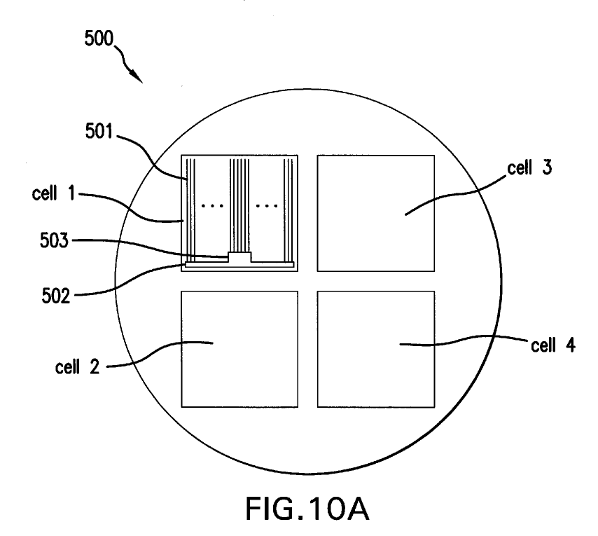

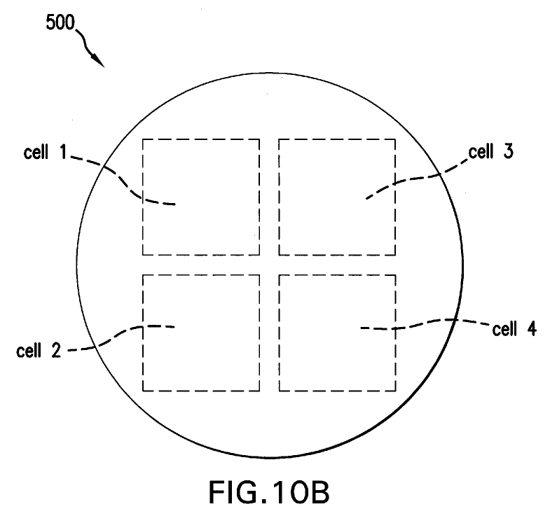

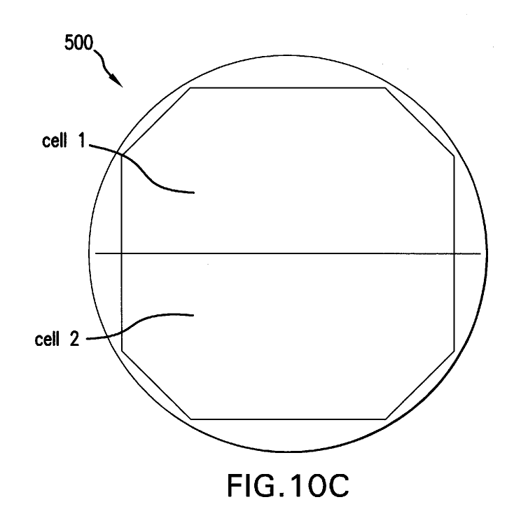

FIG. 10A is a top plan view of a 100 mm (or 4 inch) wafer in which four solar cells are implemented. The depiction of four cells is for illustration purposes only, and the present invention is not limited to any specific geometry or number of cells per wafer.

In each cell there are grid lines 501 (more particularly shown in cross-section in FIG. 9), an interconnecting bus line 502, and a contact pad 503. The geometry and number of grid and bus lines and contact pads are illustrative, and the present invention is not limited to the illustrated embodiment.

FIG. 10B is a bottom plan view of the wafer of FIG. 10A.

FIG. 10C is a top plan view of a 100 mm (or 4 inch) wafer in which two solar cells are implemented. Each solar cell has an area of 26.3 cm² and after fabrication will have a power/weight ratio (after separation from the growth and surrogate substrates, and including a 4 mil thick cover glass) of 945 mW/g. Although subsequent discussion in the present application will depict the embodiment illustrated in FIG. 10A, the processes and arrangements described herein are also applicable to solar cells of different geometries or configurations such as that of FIG. 10C.

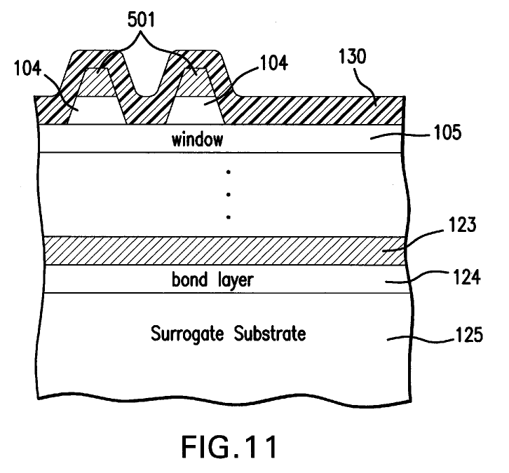

FIG. 11 is a cross-sectional view of the solar cell of FIG. 9 after the next process step in which an antireflective (ARC) dielectric coating layer 130 is applied over the entire surface of the “top” side of the wafer with the grid lines 501.

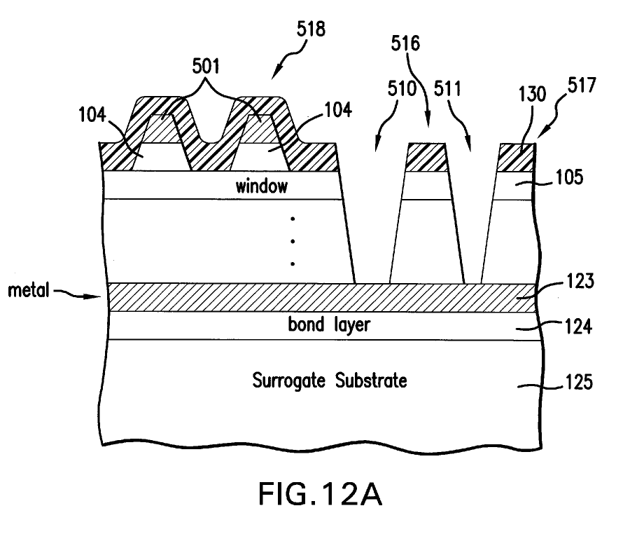

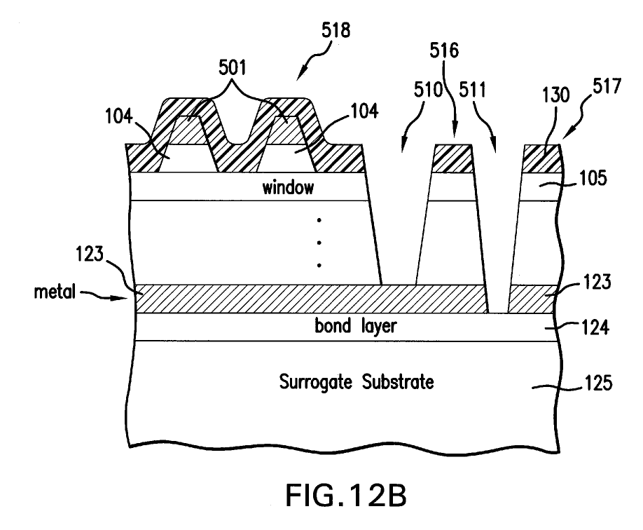

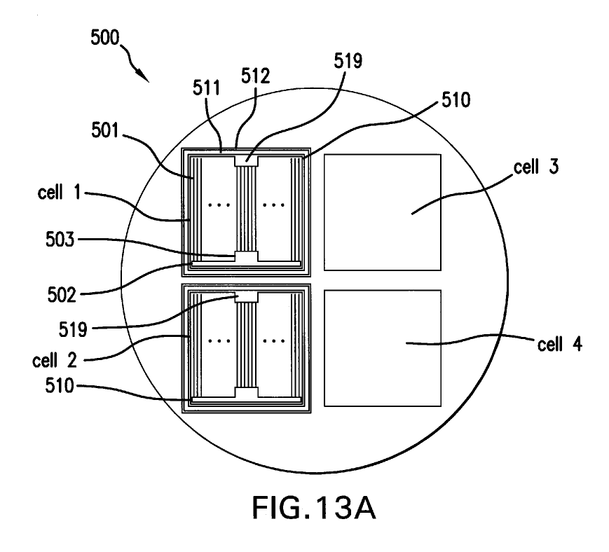

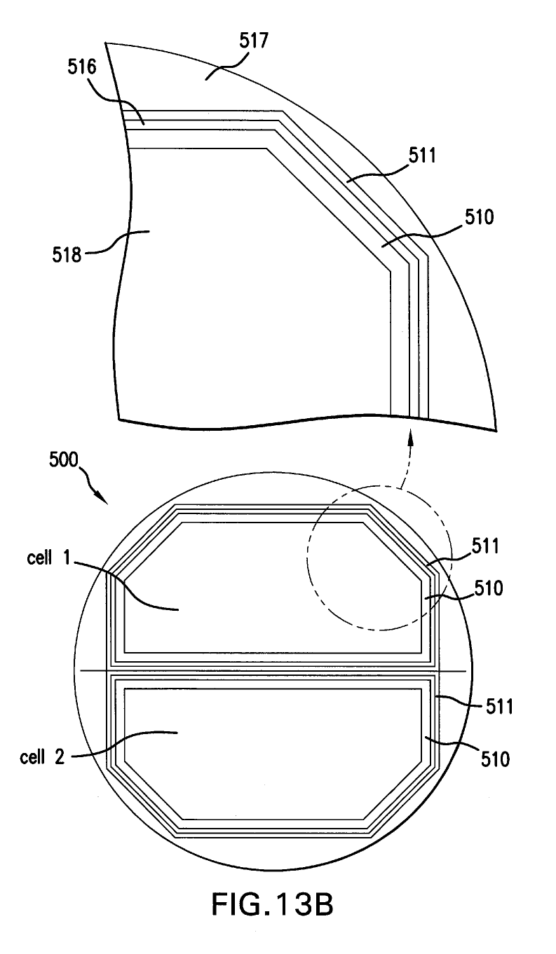

FIG. 12A is a cross-sectional view of the solar cell of FIG. 11 after the next process step according to the present invention in which first and second annular channels 510 and 511, or portion of the semiconductor structure are etched down to the metal layer 123 using phosphide and arsenide etchants. These channels, as more particularly described in U.S. patent application Ser. No. 12/190,449 filed Aug. 12, 2008, define a peripheral boundary between the cell, a surrounding mesa 516, and a periphery mesa 517 at the edge of the wafer, and leave a mesa structure 518 which constitutes the solar cell. The cross-section depicted in FIG. 12A is that as seen from the A-A plane shown in FIG. 13A.

FIG. 12B is a cross-sectional view of the solar cell of FIG. 12A after the next process step in which channel 511 is exposed to a metal etchant, layer 123 in the channel 511 is removed, and channel 511 is extended in depth approximately to the top surface of the bond layer 124.

FIG. 13A is a top plan view of the wafer of FIG. 10A after the process described in connection with FIG. 12A, depicting the channels 510 and 511 etched around the periphery of each cell. A substantially rectangular shaped cut-out 519 is formed at one of the peripheral edges of the cell and is etched simultaneously with channel 511, so that the resulting exposed area on the top surface of the back metal layer 123 will form a contact pad to allow an electrical contact to be made to the lower subcell. Similar cut-outs are formed in cells 2, 3, and 4.

FIG. 13B is a top plan view of the wafer of FIG. 10C depicting the channels 510 and 511 etched around the periphery of each cell.

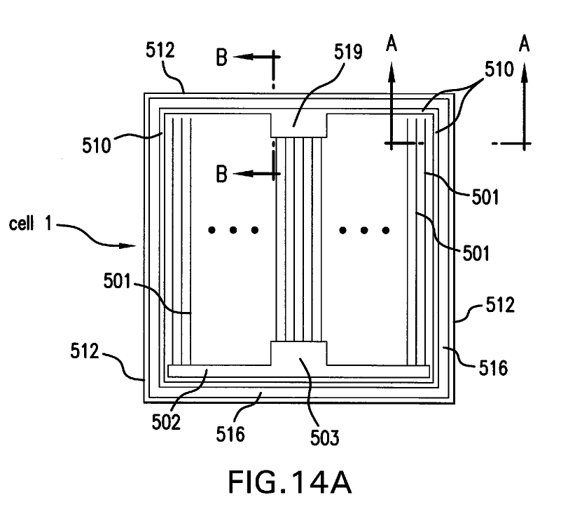

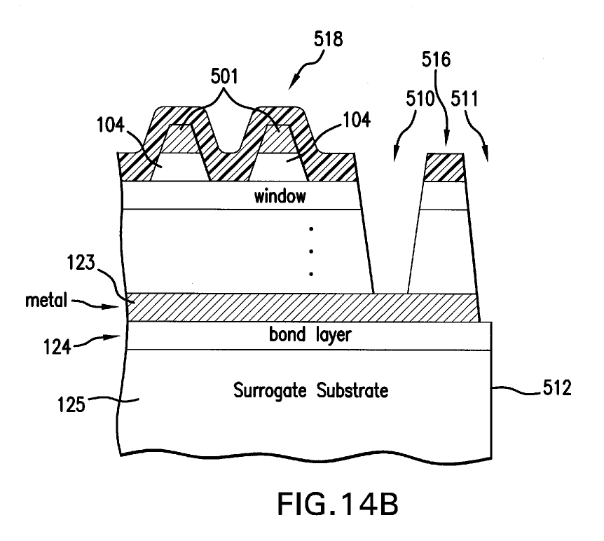

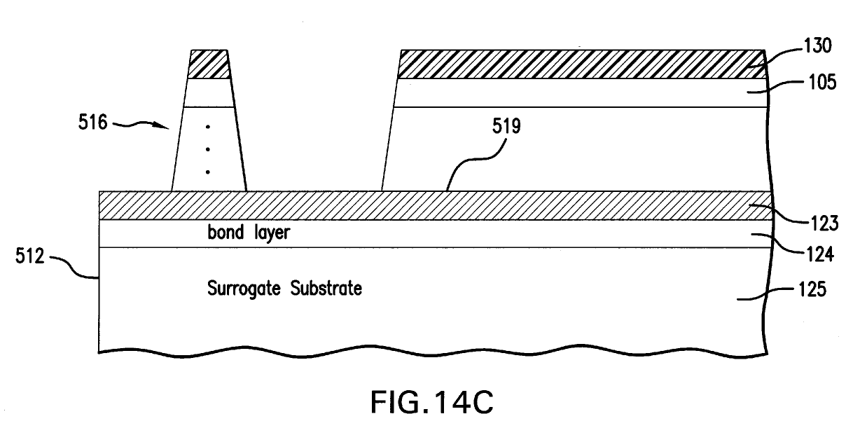

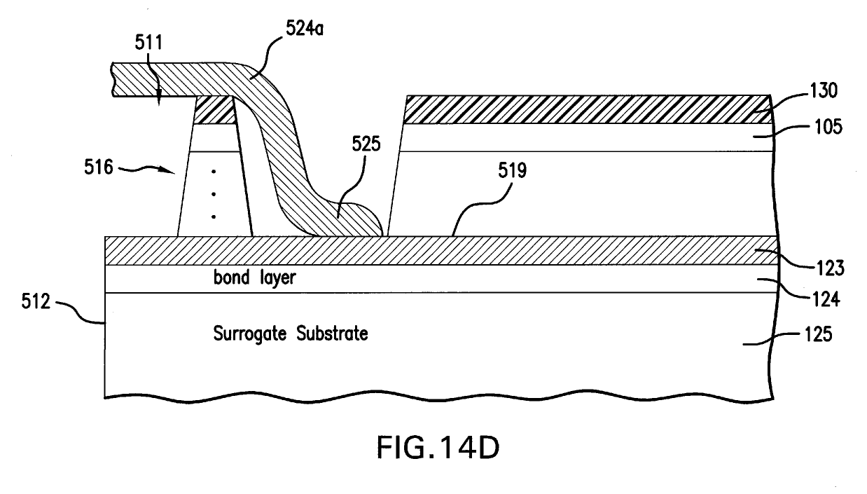

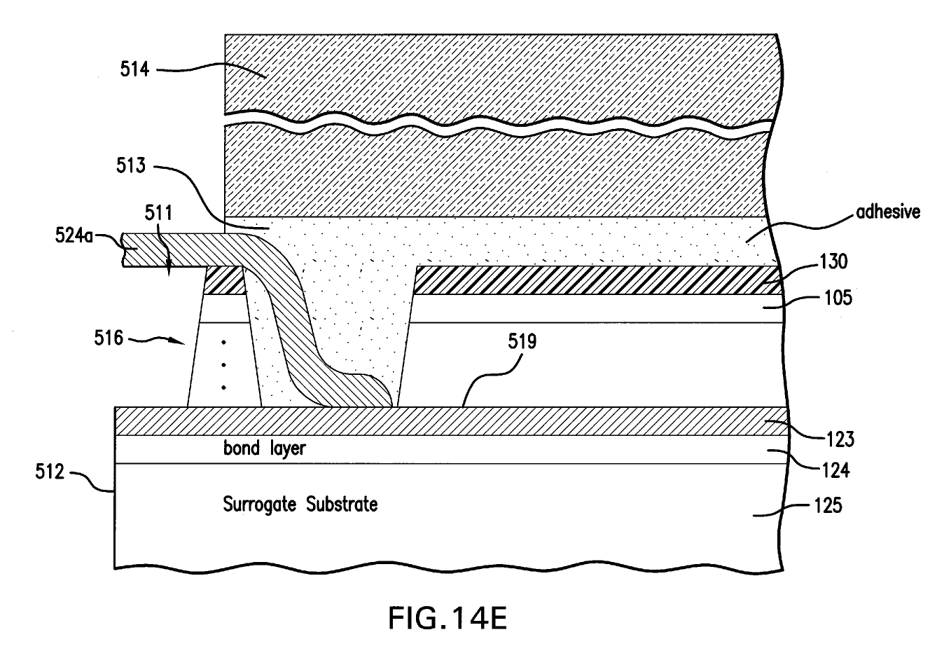

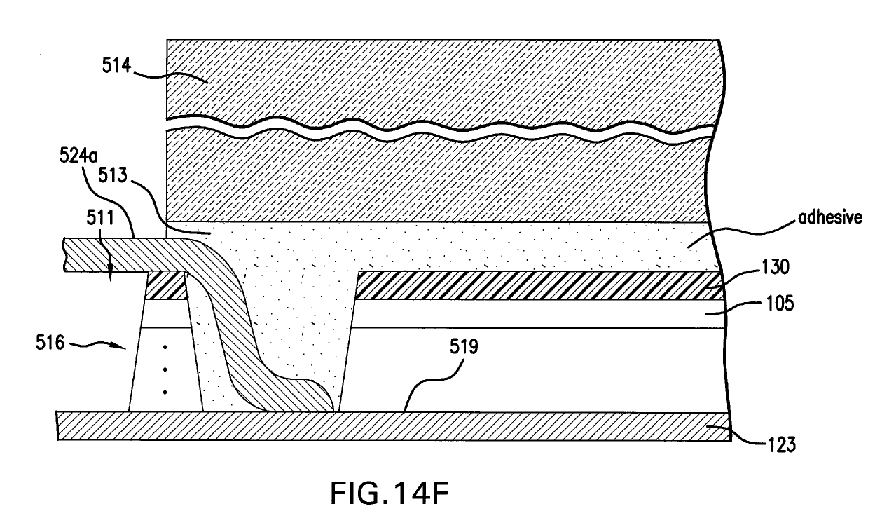

FIG. 14A is a top plan view of solar cell 1 fabricated on the wafer of FIG. 10A after the individual solar cells (cell 1, cell 2, etc. shown in FIG. 13A) are cut or scribed from the wafer through the channel 511. The channel 510 is depicted etched around the periphery of the cell, as well as the substantially rectangular shaped cut-out 519 formed at one of the peripheral edges of the cell, forming a contact pad. The mesa 516 circumferentially surrounding the cell is also depicted, and the edge 512 of the cell.

FIG. 14B is a cross-sectional view of the solar cell of FIG. 14A through the A-A plane and showing the channel 510, the mesa 516, a remaining portion of the channel 511, and the vertical edge 512 where the cut or scribe extending through the surrogate substrate 125 was made to separate the individual cells.

FIG. 14C is a cross-sectional view of the solar cell of FIG. 14A through the B-B plane and showing the contact pad 519, the mesa 516, a remaining portion of the channel 511, and the vertical edge 512.

FIG. 14D is a cross-sectional view of the solar cell of FIG. 14C after the next process step of the welding of one end 525 of the interconnection 524a to contact 520a, with the interconnection 524a arranged so that the other end 526 of the interconnection 524a rests on and extends over the mesa 516 away from the cell.

FIG. 14E is a cross-sectional view of the solar cell of FIG. 14D showing the contact pad 519, the mesa 516, a remaining portion of the channel 511, and the vertical edge 512, after a cover glass 514 is attached to the top of the cell by means of an adhesive 513.

FIG. 14F is a cross-sectional view of the solar cell of FIG. 14E after the next process step in some embodiments of the present invention in which the adhesive layer 124, the surrogate substrate 125 and the peripheral portion 517 of the wafer is entirely removed, leaving only the solar cell with the ARC layer 130 (or other layers or structures) on the top, and the metal contact layer 123 on the bottom, which forms the backside contact of the solar cell. The surrogate substrate is preferably removed by the use of a ‘Wafer Bond’ solvent. As noted above, the surrogate substrate includes perforations over its surface that allow the flow of solvent through the surrogate substrate 125 to permit its lift off. After lift off, the surrogate substrate may be reused in subsequent wafer processing operations.

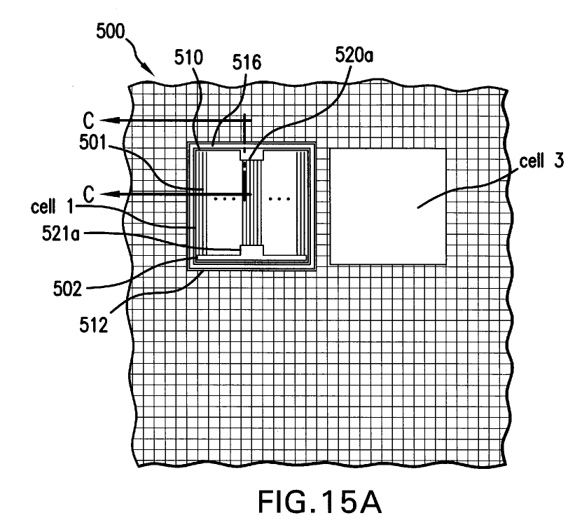

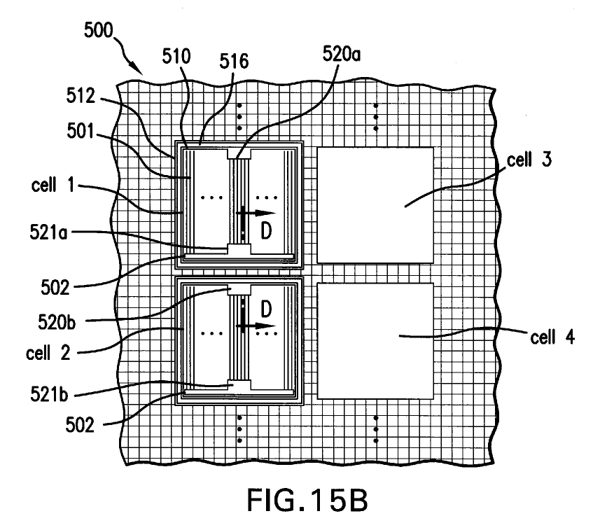

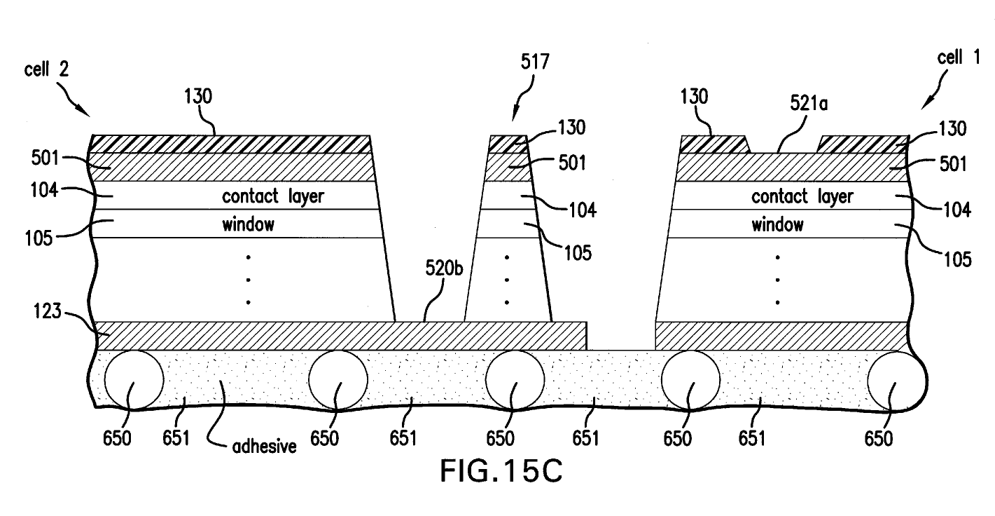

FIG. 15A is a top plan view of two of the solar cells after the solar cells have been separated from the wafer (after the cut through the channel 511) and separated from the surrogate substrate, as illustrated in FIG. 14F, with the two solar cells (representing a first row of solar cells) being positioned, aligned, and adhered to the surface of a flexible perforated carrier 650, such as a mesh formed from Ultratek™, a product of Alliant Techsystems, Inc. of Minneapolis, Minn., using an adhesive layer 651. In the preferred embodiment, the mesh is formed with square shaped perforations, with the dimensions of each square shaped aperture being approximately 0.25 cm. The Ultraflex™ mesh may be used as the finished support platform for the solar cell array. The cross sectional view of cell 1, through the C-C plane indicated in the FIG. 15A, is depicted in FIG. 16A. The interconnect 524a is not depicted in order to simplify the drawing. In some embodiments the interconnect 524a may be welded or attached to the cells after the solar cells have been separated from the wafer (after the cut through the channel 511) and separated from the surrogate substrate, as illustrated in FIG. 14D, and before the solar cells are positioned, aligned, and adhered to the surface of a flexible perforated carrier 650. In other embodiments, the solar cells may be mounted on the carrier 650 without the interconnect, and the interconnect welded to the cells while on the carrier 650.

FIG. 15B is a top plan view of the carrier depicted in FIG. 15A after the next process step in which two additional solar cells (or an additional row of cells) are mounted to the carrier adjacent to the row of the two cells depicted in FIG. 15A. The interconnect 524a is not depicted in order to simplify the drawing. In the illustrated embodiment, the bottom contact pad 521a of cell 1 is depicted as being adjacent to and aligned with the top contact 520b of cell 2. There are similar alignments of the bottom contact pads of other cells in the array as being adjacent to and aligned with the top contacts of directly adjacent cells. The cross sectional view of cells 1 and 2, through the D-D plane indicated in the FIG. 15B, is depicted in FIG. 15C.

As noted above, in some embodiments, the solar cells may be mounted on the carrier 650 without the interconnect, and the interconnect welded to the cells while on the carrier 650. FIG. 15C is a cross-sectional view of the solar cells (cell 1 and cell 2) depicted in FIG. 15B as seen from the D-D plane indicated in FIG. 15B.

As noted above, in some embodiments, an interconnect may be welded to one or both of the contacts on each cell, along with a cover glass over each cell, prior to mounting on the perforated carrier 650.

FIG. 16A is a cross-sectional view of one of the solar cells (cell 2) depicted in FIG. 15A as seen from the C-C plane indicated in FIG. 15A, in one embodiment, with the cell, together with a welded interconnect 524a attached to the contact pad 520a, being adhered to a perforated carrier 650 by an adhesive 651. In this first embodiment, the interconnection 524a is arranged so that the other end 526 of the interconnection 524a extends parallel to the carrier 650 so as to make an interconnection with an adjacent cell to be mounted on the same side of the carrier 650. In some embodiments, a cover glass is secured to the top of the cell by an adhesive, as illustrated in FIG. 14F. The cover glass 514 is typically about 4 mils thick and preferably covers the entire channel 510, extends over a portion of the mesa 517, but does not extend to channel 511. Although the use of a cover glass is desirable for many environmental conditions and applications, it is not necessary for all implementations, and additional layers or structures may also be utilized for providing additional support or environmental protection to the solar cell.

FIG. 16B is a cross-sectional view of one of the solar cells (cell 2) depicted in FIG. 15B as seen from the C-C plane indicated in FIG. 15A, with the cell, together with a welded interconnect 524a attached to the contact pad 520a, being adhered to a perforated carrier 650 by an adhesive 651. In this second embodiment, the interconnection 524a is welded and arranged so that the other end 526 of the interconnection 524a extends substantially normal to the carrier 650, so that in mounting the cell on the carrier 650, the interconnection 524a is threaded through an opening in the mesh so as to permit the end 526 to make an interconnection with another element on the underside of the carrier 650.

FIG. 16C is a cross-sectional view of one of the solar cells (cell 2) depicted in FIG. 15B as seen from the D-D plane indicated in FIG. 15B, with the cell, after the next process step of mounting a second cell (cell 1) adjacent to cell 2 on the carrier 650. The cell 2 includes the interconnection 524b welded to contact 521a. In this embodiment, the interconnect 524b is illustrated as not extending though the carrier 650.

FIG. 16D is a cross-sectional view of two of the solar cells (cell 1 and cell 2) depicted in FIG. 15B as seen from the D-D plane, with the two cells being supported on a perforated carrier 650, in an embodiment in which the end 528 of the interconnect 524b extends through the carrier 650. In this embodiment, one end 528 of the interconnection 524b is threaded through the mesh of the carrier 650 so that it is closely adjacent to the corresponding end 526 of the interconnection 524a on the backside of the carrier 650.

FIG. 16E is a cross-sectional view of two of the solar cells (cell 1 and cell 2) depicted in FIG. 16D, with the two cells being supported on a perforated carrier 650, after the next process step of welding one end 528 of the interconnection 524b to the corresponding end 526 of the interconnection 524a on the backside of the carrier 650.

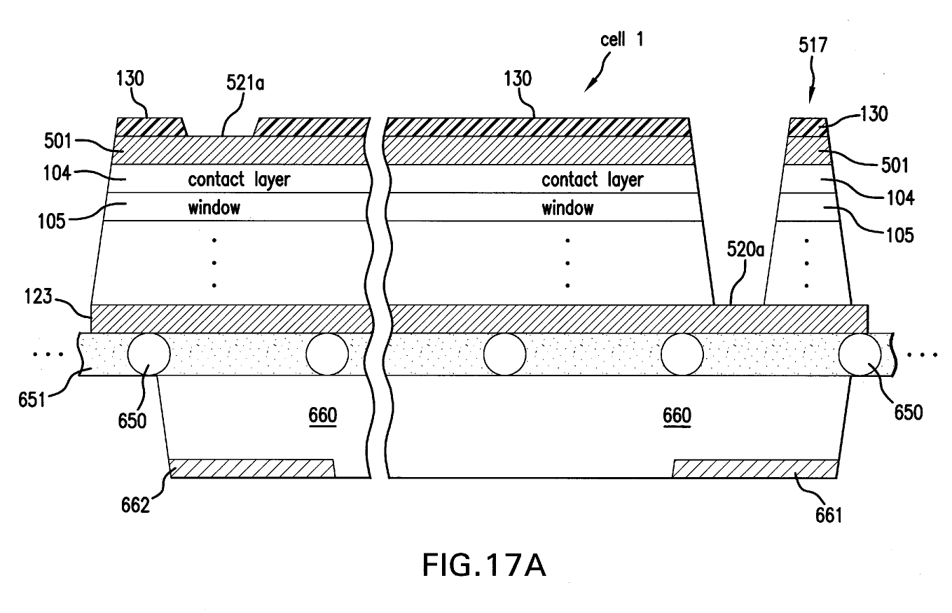

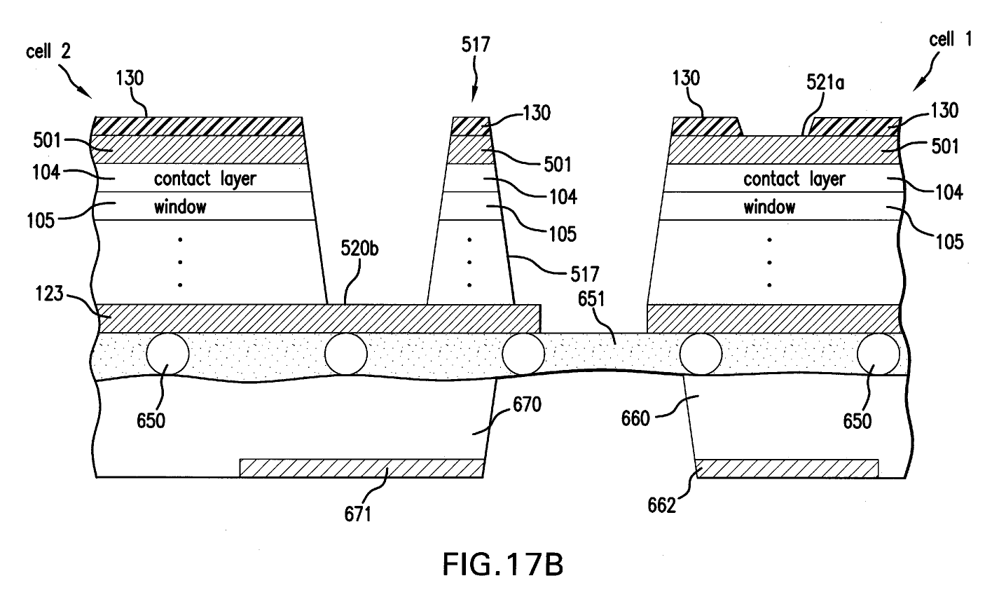

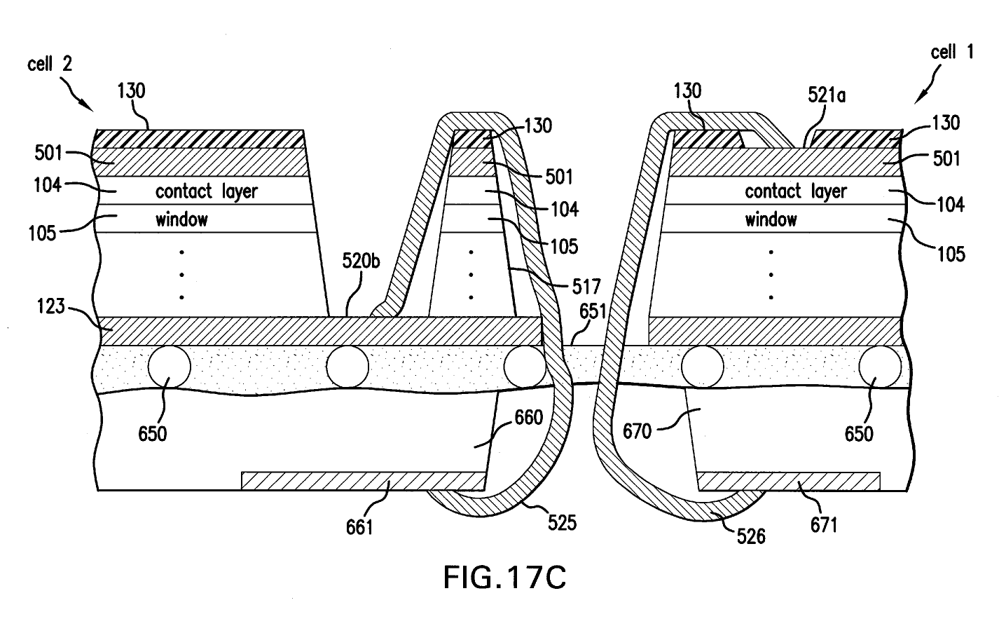

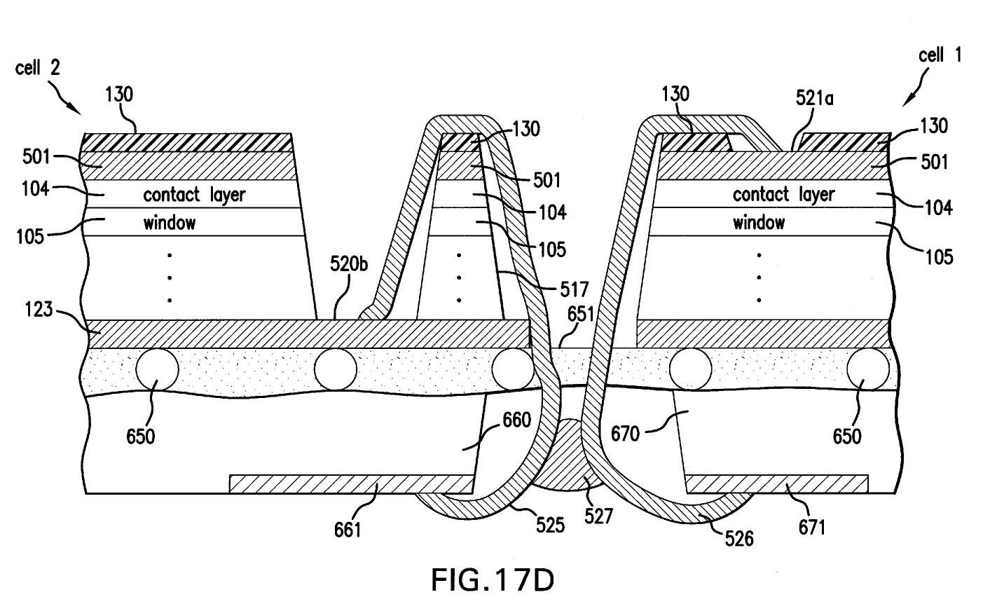

FIG. 17A is a cross-sectional view of one of the solar cells (cell 1) depicted in FIG. 15A as seen from the C-C plane indicated in FIG. 15A, with the cell being supported on a perforated carrier 650, after the next process step in another embodiment of the present invention in which a first discrete bypass diode 660 is adhesively attached to the underside of the perforated carrier 650 by the adhesive layer 651. The bypass diode 660 includes a first terminal 661 and a second terminal 662. In some embodiments, a cover glass may be provided over the cell, as shown in FIG. 14F.

FIG. 17B is a cross-sectional view of two of the solar cells (cell 1 and cell 2) depicted in FIG. 15B as seen from the D-D plane indicated in FIG. 15B, with the two cells being supported on a perforated carrier 650, after the next process step in an embodiment of the present invention in which a first discrete bypass diode 660 is adhesively attached to the underside of the perforated carrier 650 opposite cell 2. The bypass diode 660 includes a terminal 661. Similarly, a second discrete bypass diode 670 is adhesively attached to the underside of the perforated carrier 650 opposite cell 1. The Figure depicts one of the terminals 671 of the bypass diode 670, and one of the terminals 662 of the bypass diode 660.

FIG. 17C is a cross-sectional view of two of the solar cells (cell 1 and cell 2) depicted in FIG. 17B, after the next process step in an embodiment of the present invention in which an electrical interconnection 525 is made between the terminal 661 of first discrete bypass diode 660 and the contact 520b of solar cell 2. An electrical interconnection 526 is made between the terminal 671 of the second discrete bypass diode 670 and the contact 521a of solar cell 1.

FIG. 17D is a cross-sectional view of two of the solar cells (cell 1 and cell 2) depicted in FIG. 17B, after the next process step in a second embodiment of the present invention in which the electrical interconnection 525 is bonded to the electrical interconnection 526 on the underside of the carrier 650, in order to make a series electrical connection of cell 1 and cell 2.

FIG. 18 is a graph that depicts the current and voltage characteristics of the solar cell according to the present invention. The solar cell has an open circuit voltage (V_{oc}) of approximately 3.074 volts, a short circuit current of approximately 16.8 mA/cm², a fill factor of approximately 85.7%, and an efficiency (at AM0) of 32.7%.

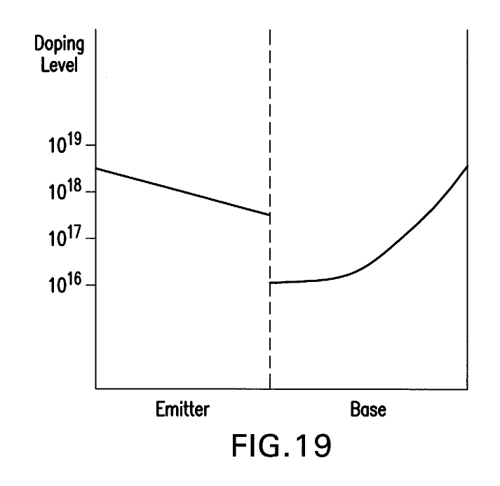

FIG. 19 is a graph of a doping profile in the emitter and base layers in one or more subcells of the inverted metamorphic multijunction solar cell of the present invention. The various doping profiles within the scope of the present invention, and the advantages of such doping profiles are more particularly described in copending U.S. patent application Ser. No. 11/956,069, filed Dec. 13, 2007, herein incorporated by reference. The doping profiles depicted herein are merely illustrative, and other more complex profiles may be utilized as would be apparent to those skilled in the art without departing from the scope of the present invention.

It will be understood that each of the elements described above, or two or more together, also may find a useful application in other types of constructions differing from the types of constructions described above.

Although the preferred embodiment of the present invention utilizes a vertical stack of three subcells, the present invention can apply to stacks with fewer or greater number of subcells, i.e. two junction cells, four junction cells, five junction cells, etc. as more particularly described in U.S. patent application Ser. No. 12/267,812, filed Nov. 10, 2008. In the case of four or more junction cells, the use of more than one metamorphic grading interlayer may also be utilized, as more particularly described in U.S. patent application Ser. No. 12/271,192, filed Nov. 14, 2008.

In addition, although the present embodiment is configured with top and bottom electrical contacts, the subcells may alternatively be contacted by means of metal contacts to laterally conductive semiconductor layers between the subcells. Such arrangements may be used to form 3-terminal, 4-terminal, and in general, n-terminal devices. The subcells can be interconnected in circuits using these additional terminals such that most of the available photogenerated current density in each subcell can be used effectively, leading to high efficiency for the multijunction cell, notwithstanding that the photogenerated current densities are typically different in the various subcells.

As noted above, the present invention may utilize an arrangement of one or more, or all, homojunction cells or subcells, i.e., a cell or subcell in which the p-n junction is formed between a p-type semiconductor and an n-type semiconductor both of which have the same chemical composition and the same band gap, differing only in the dopant species and types, and one or more heterojunction cells or subcells. Subcell A, with p-type and n-type InGaP is one example of a homojunction subcell. Alternatively, as more particularly described in U.S. patent application Ser. No. 12/023,772, filed Jan. 31, 2008, the present invention may utilize one or more, or all, heterojunction cells or subcells, i.e., a cell or subcell in which the p-n junction is formed between a p-type semiconductor and an n-type semiconductor having different chemical compositions of the semiconductor material in the n-type regions, and/or different band gap energies in the p-type regions, in addition to utilizing different dopant species and type in the p-type and n-type regions that form the p-n junction.

In some cells, a thin so-called “intrinsic layer” may be placed between the emitter layer and base layer, with the same or different composition from either the emitter or the base layer. The intrinsic layer may function to suppress minority-carrier recombination in the space-charge region. Similarly, either the base layer or the emitter layer may also be intrinsic or not-intentionally-doped (“NID”) over part or all of its thickness. Some such configurations are more particularly described in copending U.S. patent application Ser. No. 12/253,051, filed Oct. 16, 2008.

The composition of the window or BSF layers may utilize other semiconductor compounds, subject to lattice constant and band gap requirements, and may include AlInp, AlAs, AlP, AlGaInP, AlGaAsP, AlGaInAs, AlGaInPAs, GaInP, GaInAs, GaInPAs, AlGaAs, AlInAs, AlInPAs, GaAsSb, AlAsSb, GaAlAsSb, AlInSb, GaInSb, AlGaInSb, AIN, GaN, InN, GaInN, AlGaInN, GaInNAs, AlGaInNAs, ZnSSe, CdSSe, and similar materials, and still fall within the spirit of the present invention.

While the invention has been illustrated and described as embodied in an inverted metamorphic multijunction solar cell, it is not intended to be limited to the details shown, since various modifications and structural changes may be made without departing in any way from the spirit of the present invention.

Thus, while the description of this invention has focused primarily on solar cells or photovoltaic devices, persons skilled in the art know that other optoelectronic devices, such as thermophotovoltaic (TPV) cells, photodetectors and light-emitting diodes (LEDS), are very similar in structure, physics, and materials to photovoltaic devices with some minor variations in doping and the minority carrier lifetime. For example, photodetectors can be the same materials and structures as the photovoltaic devices described above, but perhaps more lightly-doped for sensitivity rather than power production. On the other hand LEDs can also be made with similar structures and materials, but perhaps more heavily-doped to shorten recombination time, thus radiative lifetime to produce light instead of power. Therefore, this invention also applies to photodetectors and LEDs with structures, compositions of matter, articles of manufacture, and improvements as described above for photovoltaic cells.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

1. A method of forming a multijunction solar cell string comprising:
providing a first multijunction solar cell including a contact pad disposed adjacent the top surface of the multijunction solar cell along a first peripheral edge thereof;
providing a second multijunction solar cell disposed adjacent said first multijunction solar cell, having a top surface and a bottom surface, and including a cut-out extending from a second peripheral edge along the top surface of the second solar cell located adjacent the first peripheral edge of said first multijunction solar cell, and extending to a metal contact layer adjacent the bottom surface of said second multijunction solar cell to allow an electrical contact to be made to the metal contact layer;
mounting said first and said second multijunction solar cells on a first side of a perforated carrier;
attaching a first electrical interconnect to the contact pad of said first multijunction solar cell, a portion of the electrical interconnect extending through said perforated carrier;
attaching a second electrical interconnect to the metal contact layer of said second multijunction solar cell, a portion of the electrical interconnect extending through said perforated carrier;
mounting a cover glass over each of said first and said second multijunction solar cells; and
connecting said first electrical interconnect to said second electrical interconnect.

2. A method of forming a multijunction solar cell string as defined in claim 1, wherein said portion of the first electrical interconnect extending through said perforated carrier is connected to the respective portion of the second electrical interconnect extending through said perforated carrier by welding.

3. A method of forming a multijunction solar cell string of claim 1, wherein the number of cut-outs of said second multijunction solar cell is equal to the number of contact pads of said first multijunction solar cell, and the spacing of such cut-outs is substantially similar to the spacing of the contact pads along the respective second and first peripheral edges to facilitate the electrical interconnection of the contact pads on said first multijunction solar cell by a plurality of electrical interconnects.

4. A method of forming a multijunction solar cell string of claim 1, wherein the perforated carrier is composed of a flexible composite material.

5. A method of forming a multijunction solar cell string of claim 1, wherein the perforated carrier is composed of an UltraFlex™ mesh.

6. A method of forming a multijunction solar cell string of claim 1, wherein the perforated carrier has perforations that are approximately square in shape and approximately 0.25 cm in width.

7. A method of forming a multijunction solar cell string of claim 1, farther comprising attaching a discrete bypass diode to the second side of the perforated carrier, and electrically connecting the respective terminals of the bypass diode to the terminals of the corresponding solar cell on the first side of the perforated carrier.

8. A method of forming a multijunction solar cell string of claim 1, wherein the electrical interconnects are discrete planar metal strips welded to the contact pad on the first multijunction solar cell and to the metal layer on the second multijunction solar cell.

9. A method of forming a multijunction solar cell string of claim 1, wherein providing a first multijunction solar cell comprises:
providing a first substrate for the epitaxial growth of semiconductor material;
forming an upper first solar subcell on said first substrate having a first band gap;
forming a middle second solar subcell over said first solar subcell having a second band gap smaller than said first band gap;
forming a graded interlayer over said second solar cell;
forming a lower third solar subcell over said graded interlayer having a fourth band gap smaller than said second band gap such that said third subcell is lattice mismatched with respect to said second subcell, and including a metal contact layer;
attaching a surrogate second substrate over said third solar subcell and removing said first substrate; and
etching a first trough around the periphery of said solar cell to the metal contact layer so as to form a mesa structure on said surrogate second substrate and at least one bottom contact pad on said metal layer.

10. The method as defined in claim 10, wherein the contact metal layer is a sequence of metal layers including Ti/Au/Ag/Au.

11. A method of forming a multijunction solar cell as defined in claim 10, wherein providing a first multijunction solar cell comprises:
forming a first subcell comprising a first semiconductor material with a first band gap and a first lattice constant;
forming a second subcell comprising a second semiconductor material with a second band gap and a second lattice constant, wherein the second band gap is less than the first band gap and the second lattice constant is greater than the first lattice constant to the second lattice constant; and
forming a lattice constant transition material positioned between the first subcell and the second subcell, said lattice constant transition material having a lattice constant that changes gradually from the first lattice constant to the second lattice constant.

12. A method as defined in claim 11, wherein said transition material is composed of any of the As P, N, Sb based II-V compound semiconductors subject to the constraints of having the in-plane lattice parameter greater or equal to that of the first subcell and less than or equal to that of the second subcell, and having a band gap energy greater than that of the second subcell, and the band gap of the transition material remains constant at approximately 1.50 eV throughout its thickness.

13. A method as defined in claim 11, wherein the transition material is composed of a sequence of (InₓGa₁₋ₓ)_{y}Al_{1-y}As layers, with x and y selected such that the band gap of each layer remains constant throughout the thickness of the transition material.

14. A method as defined in claim 11, wherein said first subcell is composed of an GaInP, GaAs, GaInAs, GaAsSb, or GaInAsN emitter region and an GaAs, GaInAs, GaAsSb, or GaInAsN base region, and the second subcell is composed of InGaAs base and emitter regions.

15. A multijunction solar cell comprising:
an upper first solar subcell having a first band gap disposed adjacent the top surface of the multijunction solar cell;
a middle second solar subcell adjacent to said first solar subcell and having a second band gap smaller than said first band gap;
a graded interlayer adjacent to said second solar subcell; said graded interlayer having a third band gap greater than said second band gap; and
a bottom third solar subcell adjacent to said interlayer, said bottom subcell having a fourth band gap smaller than said second band gap such that said third subcell is lattice mismatched with respect to said second subcell;
a metal contact layer adjacent to said third solar subcell for making an electrical contact thereto;
a cut-out extending from a peripheral edge along the top surface of the solar cell to the metal contact layer to allow an electrical contact to be made to the bottom subcell from the top surface of the solar cell; and
a perforated carrier supporting the multijunction solar cell.

16. A multijunction solar cell string of claim 15, wherein the perforated carrier is composed of a flexible composite material.

17. A multijunction solar cell of claim 15, wherein the perforated carrier is composed of an UltraFlex™ mesh.

18. The multijunction solar cell of claim 15, wherein the graded interlayer is compositionally graded to lattice match the middle subcell on one side and the bottom subcell on the other side and is composed of any of the As, P. N, Sb based III-V compound semiconductors subject to the constraints of having the in-plane lattice parameter greater or equal to that of the middle subcell and less than or equal to that of the bottom subcell, and having a band gap energy greater than that of the middle subcell.

19. The multijunction solar cell as defined in claim 15, further comprising a discrete bypass diode mounted on the second side of the perforated carrier, with the respective terminals of the bypass diode being connected to the terminals of the corresponding solar cell on the first side of the perforated carrier.

20. A multijunction solar cell string comprising:
a first multijunction solar cell including a contact pad disposed adjacent the top surface of the multijunction solar cell along a first peripheral edge thereof;
a second multijunction solar cell disposed adjacent said first multijunction solar cell, having a top surface and a bottom surface, and including a cut-out extending from a second peripheral edge along the top surface of the second solar cell located adjacent the first peripheral edge of said first multijunction solar cell, and extending to a metal contact layer adjacent the bottom surface of said second multijunction solar cell to allow an electrical contact to be made to the metal contact layer;
a perforated carrier having a first side supporting the first and second multijunction solar cells;
first and second discrete bypass diodes mounted on the second side of the perforated carrier, each diode having first and second terminals; and
an electrical interconnect extending at least between the contact pad of said first multijunction solar cell and the corresponding terminal of the first bypass diode through the perforated carrier.
